(19) United States
(12) Patent Application Publication
(10) Pub. No.: US 2026/0211283 A1
(43) Pub. Date: Jul. 23, 2026

(54) DISPLAY APPARATUS

(71) Applicant: SAMSUNG ELECTRONICS CO., LTD., Suwon-si (KR)

(72) Inventors: Taeyeon KIM, Suwon-si (KR); Hungsuk Kim, Suwon-si (KR); Chunsoon Park, Suwon-si (KR); Youngmin Lee, Suwon-si (KR); Hyukjun Jang, Suwon-si (KR)

(73) Assignee: SAMSUNG ELECTRONICS CO., LTD., Suwon-si (KR)

(21) Appl. No.: 19/646,166

(22) Filed: Apr. 13, 2026

Related U.S. Application Data
(63) Continuation of application No. PCT/KR2024/013772, filed on Sep. 11, 2024.

(30) Foreign Application Priority Data
Nov. 3, 2023 (KR) 10-2023-0151232

(51) Int. Cl. G02F 1/13357; G02F 1/1335; H10D 86/60; H10H 29/30

(52) U.S. Cl. CPC G02F 1/133611; G02F 1/133603; G02F 1/133608; G02F 1/133612; H10D 86/60; H10H 29/30

(57) ABSTRACT

A display apparatus includes a display panel; a plurality of light sources which are configured to emit light toward the display panel and include first light sources and second light sources; and a plurality of substrate bars to which the plurality of light sources are mounted. Each substrate bar includes: a central extension portion extending in a first direction; a first protruding portion protruding in a second direction different from the first direction from the central extension portion and on which the first light sources are mounted; and a second protruding portion protruding in a third direction opposite to the second direction from the central extension portion and on which the second light sources are mounted. Some substrate bars have a shape from the first light source to the first protruding portion that is different from a shape from the second light source to the second protruding portion.

### CROSS-REFERENCE TO RELATED APPLICATIONS

This application is a continuation of International Application No. PCT/KR2024/013772, filed on September 11, 2024, which is based on and claims priority to Korean Patent Application No. 10-2023-0151232, filed on November 3, 2023, in the Korean Intellectual Property Office, the disclosures of which are incorporated by reference herein in their entireties.

### BACKGROUND

### 1. Field

The disclosure relates to a display apparatus and, more particularly, to a display apparatus including a light source substrate structure for a backlight unit.

### 2. Description of Related Art

A display apparatus converts obtained or stored electrical information into visual information and displays the visual information to a user, and the display apparatus is used in various fields, such as a home or a workplace.

The display apparatus includes a monitor apparatus connected to a personal computer or a server computer, a portable computer device, a navigation terminal device, a general television apparatus, an Internet Protocol television (IPTV), a portable terminal device, such as a smart phone, a tablet PC, a personal digital assistant (PDA) or a cellular phone, various display apparatuses used to reproduce images, such as advertisements or movies in an industrial field, or various kinds of audio/video systems.

The display apparatus may include a light source module to convert electrical information to visual information, and the light source module may include a plurality of light sources to separately emit light. Each of the plurality of light sources may include, for example, a light emitting diode (LED) or an organic LED (OLED), and the LED or the OLED may be mounted on a circuit board or a substrate.

### SUMMARY

Provided is a display apparatus in which a light source substrate may be stably fixed within a main body.

Further, provided is a display apparatus which may have an improved structure that enables enhanced uniformity of luminance.

Further, provided is a display apparatus which may have an improved structure that enables reduction of product cost and/or manufacturing cost.

The technical objectives of the disclosure are not limited to the above, and other objectives that are not described above will be clearly understood by those skilled in the art from the above detailed description.

According to an aspect of the disclosure, a display apparatus includes: a display panel; a plurality of light sources configured to emit light toward the display panel and including first light sources and second light sources; and a plurality of substrate bars on which the plurality of light sources are mounted, wherein each of the plurality of substrate bars includes: a central extension portion extending in a first direction; a first protruding portion protruding from the central extension portion in a second direction different from the first direction, a first light source among the first light sources being mounted on the first protruding portion; and a second protruding portion protruding from the central extension portion in a third direction opposite to the second direction, a second light source among the second light sources being mounted on the second protruding portion, wherein in at least one of the plurality of substrate bars, a shape from the first light source to the first protruding portion is different from a shape from the second light source to the second protruding portion.

In at least one of the plurality of substrate bars, a distance from the first light source to an edge of the first protruding portion may be different from a distance from the second light source to an edge of the second protruding portion.

The plurality of substrate bars may include: a first substrate bar at an end in the second direction among the plurality of substrate bars; and a second substrate bar at an end in the third direction among the plurality of substrate bars, a distance from the first light source mounted on the first substrate bar to the edge of the first protruding portion of the first substrate bar may be greater than a distance from the second light source mounted on the first substrate bar to the edge of the second protruding portion of the first substrate bar, and a distance from the second light source mounted on the second substrate bar to the edge of the second protruding portion of the second substrate bar may be greater than a distance from the first light source mounted on the second substrate bar to the edge of the first protruding portion of the second substrate bar.

The plurality of substrate bars may further include a third substrate bar between the first substrate bar and the second substrate bar, the distance from the first light source mounted on the first substrate bar to the edge of the first protruding portion of the first substrate bar may be greater than a distance from the first light source mounted on the third substrate bar to the edge of the first protruding portion of the third substrate bar, and the distance from the second light source mounted on the second substrate bar to the edge of the second protruding portion of the second substrate bar may be greater than a distance from the second light source mounted on the third substrate bar to the edge of the second protruding portion of the third substrate bar.

The display apparatus may further include: a bottom chassis on which the plurality of substrate bars are disposed; and a middle mold coupled to the bottom chassis and configured to fix the first protruding portion of the first substrate bar and the second protruding portion of the second substrate bar.

The first protruding portion of the first substrate bar and the second protruding portion of the second substrate bar may be between the middle mold and the bottom chassis.

Each of the second direction and the third direction may be perpendicular to the first direction.

The display apparatus may further include a plurality of bar fixers on the central extension portion and configured to fix the plurality of substrate bars to the bottom chassis.

The display apparatus may further include: an optical member disposed between the display panel and the plurality of light sources; and a supporter on the central extension portion of the third substrate bar and supporting the optical member.

The first protruding portion may include a plurality of first protruding portions, the second protruding portion may include a plurality of second protruding portions, and each of the plurality of substrate bars may further include: a plurality of first recess portions, each first recess portion being between a pair of adjacent first protruding portions among the plurality of first protruding portions; and a plurality of second recess portions, each second recess portions being between a pair of adjacent second protruding portions among the plurality of second protruding portions.

The display apparatus may further include a reference mark having a step difference along the second direction with respect to the plurality of first recess portions, and a distance between the plurality of first protruding portions and the reference mark is smaller than a distance between the plurality of first protruding portions and the plurality of first recess portions.

The display apparatus may further include a substrate body on which light sources of the plurality of light sources are mounted and extending in the second direction, the substrate body being connected to the plurality of substrate bars, and each of the plurality of substrate bars extends from the substrate body.

Some of the light sources mounted on the substrate body may be arranged parallel to the first light sources mounted on the plurality of first protruding portions along the first direction, and

other light sources of the light sources mounted on the substrate body may be arranged parallel to the second light sources mounted on the plurality of second protruding portions along the first direction.

The display apparatus may further include a plurality of driving elements mounted on a surface of the substrate body facing the display panel and configured to control at least some of the light sources among the plurality of light sources, the plurality of driving elements may be arranged at different positions in the second direction, and at least one driving element of the plurality of driving elements may be arranged at a position in the first direction different from a position of at least one other driving element among the plurality of driving elements.

The plurality of driving elements may include: a first column of driving elements arranged along the second direction; and a second column of driving elements spaced apart from the first column of driving elements and arranged along the second direction, and each of the driving elements in the first column and each of the driving elements in the second column may be arranged to be spaced apart from each other in the second direction.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a perspective view illustrating a display apparatus according to an embodiment of the present disclosure;

FIG. 2 is an exploded view illustrating a display apparatus according to an embodiment of the present disclosure;

FIG. 3 is a cross-sectional view illustrating a display panel of a display apparatus according to an embodiment of the present disclosure;

FIG. 4 is an enlarged view illustrating a backlight unit of a display apparatus according to an embodiment of the present disclosure;

FIG. 5 is a schematic view illustrating a coupling between a light source and a reflective sheet of a display apparatus according to an embodiment of the present disclosure;

FIG. 6 is a view illustrating a light source substrate and a bottom chassis of a display apparatus according to an embodiment of the present disclosure;

FIG. 7 is an enlarged view illustrating a light source substrate and a bottom chassis of a display apparatus according to an embodiment of the present disclosure;

FIG. 8 is an enlarged view illustrating a portion of a light source substrate of a display apparatus according to an embodiment of the present disclosure;

FIG. 9 is an enlarged view illustrating a portion of a light source substrate of a display apparatus according to an embodiment of the present disclosure;

FIG. 10 is an enlarged view illustrating a light source substrate and a bottom chassis of a display apparatus according to an embodiment of the present disclosure;

FIG. 11 is an enlarged view illustrating a portion of a light source substrate of a display apparatus according to an embodiment of the present disclosure;

FIG. 12 is an enlarged view illustrating a portion of a light source substrate of a display apparatus according to an embodiment of the present disclosure;

FIG. 13 is a cross-sectional view illustrating a display apparatus according to an embodiment of the present disclosure;

FIG. 14 is an enlarged view illustrating a portion of a substrate bar and a bottom chassis of a display apparatus according to an embodiment of the present disclosure;

FIG. 15 is an enlarged view illustrating a substrate bar and a bar fixer coupled thereto in a display apparatus according to an embodiment of the present disclosure;

FIG. 16 is an enlarged view illustrating a portion of a light source module of a display apparatus according to an embodiment of the present disclosure; and

FIG. 17 is a schematic view illustrating a light source substrate of a display apparatus according to an embodiment of the present disclosure.

### DETAILED DESCRIPTION

The embodiments described in the disclosure and the configurations shown in the drawings are only examples of the disclosure, and various modifications may be made at the time of filing of the disclosure to replace the embodiments and drawings of the disclosure.

In the description of the drawings, like numbers refer to like elements throughout the description of the drawings.

The terms used herein are for the purpose of describing the embodiments and are not intended to restrict and/or to limit the disclosure. The singular expressions herein may include plural expressions, unless the context clearly dictates otherwise. In addition, the terms “comprises”, “includes”, and “has” are intended to indicate that there are features, numbers, steps, operations, elements, parts, or combinations thereof described in the disclosure, and do not exclude the presence or addition of one or more other features, numbers, steps, operations, elements, parts, or combinations thereof.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

As used herein, expressions such as “at least one of,” when preceding a list of elements, modify the entire list of elements and do not modify the individual elements of the list. For example, the expression, "at least one of A, B, and C," should be understood as including only A, only B, only C, both A and B, both A and C, both B and C, or all of A, B, and C.

As used herein, the term “and/or” includes any and all combinations of one or more of associated listed items.

It will be understood that, although the terms first, second, etc. used in the disclosure may be used herein to describe various components, these components should not be limited by these terms. These terms are only used to distinguish one component from another. For example, a first element could be termed a second element, and similarly, a second element could be termed a first element without departing from the scope of the disclosure. The term “and/or” includes combinations of one or all of a plurality of associated listed items.

In addition, the meaning of “identical” or “same” in the disclosure may include having similar properties or similarity within a certain range. In addition, “identical” or “same” refers to “substantially identical”. It should be understood that the meaning of “substantially identical” refers to a value that falls within an error range in manufacturing or a value having a difference within a range that does not have significance with respect to a reference value.

The terms, such as “part”, “device”, “block”, “member”, “module”, and the like may refer to a unit for processing at least one function or act. For example, the terms may refer to at least process processed by at least one hardware, such as a field-programmable gate array (FPGA) and/or application specific integrated circuit (ASIC), software stored in memories, or processors.

In the following description, the terms “front,” “rear,” “left,” and “ right,” are defined based on the directions illustrated in the drawings, but the terms need not restrict the shape and position of the respective components.

In addition, the terms “first direction,” “second direction,” and “third direction” used in the following description are defined with reference to the drawings, and the shapes and positions of the respective components are not limited by these terms. For example, although the first direction is described as representing a horizontal direction, it may alternatively represent a vertical direction or a front-rear direction. Further, although the second direction and the third direction are described as directions perpendicular to the first direction and opposite to each other, such as an upward direction and/or a downward direction, they may alternatively represent a left-right direction or a front-rear direction.

Hereinafter, embodiments according to the disclosure will be described in detail with reference to the accompanying drawings.

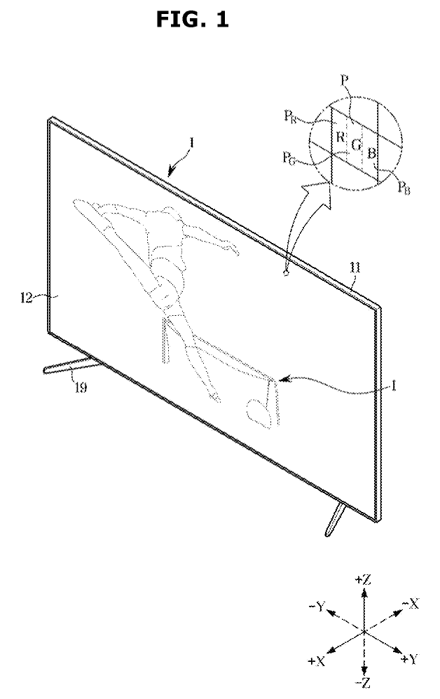

FIG. 1 is a perspective view illustrating a display apparatus according to an embodiment of the present disclosure.

Referring to FIG. 1, a display apparatus 1 according to an embodiment of the disclosure is a device that processes an image signal received from an outside and visually displays the processed image. The display apparatus 1 may include a television, but the disclosure is not limited thereto. For example, the display apparatus 1 may be implemented in various forms, such as a monitor which is a type of computer output device, a portable multimedia device, and a portable communication device, and the display apparatus 1 is not limited in the type thereof as long as it may visually display an image.

In addition, the display apparatus 1 may be a large format display (LFD) installed outdoors, such as a roof of a building or a bus stop. The term “outdoor” is not limited to the outside of a building, and the display apparatus 1 according to an embodiment of the disclosure may be installed in any places as long as the display apparatus is accessed by a large number of people, even indoors, such as subway stations, shopping malls, movie theaters, companies, and stores.

FIG. 1 illustrates a flat display apparatus with a flat screen as the display apparatus 1, but the disclosure is not limited thereto. Therefore, the display apparatus according to the disclosure may be applied to a curved display apparatus or a bendable or flexible display apparatus in which a flat state and a curved state are variable. Further, a configuration of the disclosure may be applied to display apparatus of various shapes regardless of a screen size or ratio of the display apparatus.

The display apparatus 1 may receive content data including video signals and audio signals from various content sources and output video and audio corresponding to the video signals and the audio signals. For example, the display apparatus 1 may receive content data through a broadcast reception antenna or cable, receive content data from a content playback device, or receive content data from a content providing server of a content provider.

The display apparatus 1 may display an image corresponding to video data and output sound corresponding to audio data. For example, the display apparatus 1 may restore a plurality of image frames included in video data and continuously display the plurality of image frames. Further, the display apparatus 1 may restore an audio signal included in the audio data and continuously output sound according to the audio signal.

The display apparatus 1 according to an embodiment may include a main body 11, and a screen 12 provided to display an image I.

The display apparatus 1 may be installed on an indoor or outdoor floor or furniture in a standing manner, or may be installed on a wall or inside a wall in a wall-mounted manner. For example, the display apparatus 1 may include support legs 19 provided in a lower portion of the main body 11 to be installed on the indoor or outdoor floor or furniture in the standing manner.

The main body 11 may form an appearance of the display apparatus 1. Components for forming various functions, such as allowing the display apparatus 1 to display the image I may be provided inside the main body 11.

The display apparatus 1 may be configured to display the image I. For example, the screen 12 may be formed on a front surface of the main body 11, and the display apparatus 1 may display the image I on the screen 12. For example, the screen 12 may display a still image or a moving image. Further, the screen 12 may display a two-dimensional plane image or a three-dimensional image using binocular parallax of the user.

A plurality of pixels P may be formed on the screen 12. The image I displayed on the screen 12 may be formed by light emitted from the plurality of pixels P. For example, the image I may be formed on the screen 12 by combining light emitted from the plurality of pixels P as a mosaic.

Each of the plurality of pixels P may emit different brightness and different color of light. For example, the plurality of pixels P may include sub-pixels P_{R}, P_{G}, and P_{B}, respectively, and the sub-pixels P_{R}, P_{G}, and P_{B} may include a red sub pixel P_{R} emitting red light, a green sub pixel P_{G} emitting green light, and a blue sub pixel P_{B} emitting blue light. The red light may represent a light beam having a wavelength of approximately 620 nm (nanometers, one billionth of a meter) to 750 nm, the green light may represent a light beam having a wavelength of approximately 495 nm to 570 nm, and the blue light may represent a light beam having a wavelength of approximately 450 nm to 495 nm.

By combining the red light of the red sub pixel P_{R}, the green light of the green sub pixel P_{G} and the blue light of the blue sub pixel P_{B}, each of the plurality of pixels P may emit different brightness and different color of light.

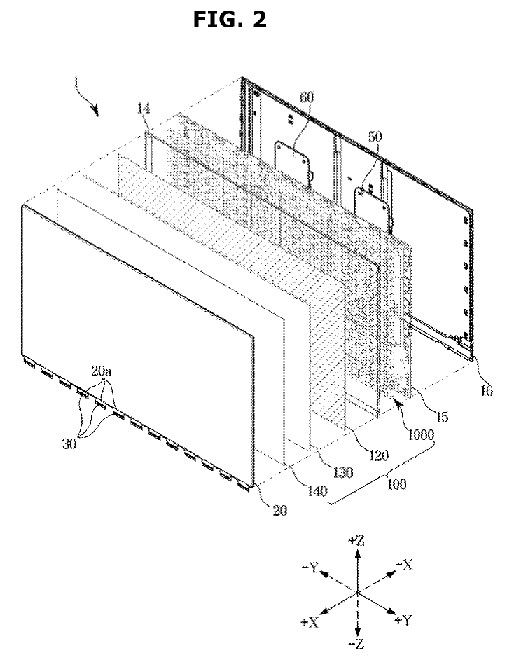

FIG. 2 is an exploded view of the display apparatus according to an embodiment of the present disclosure.

Referring to FIG. 2, various components for generating an image I on a screen 12 may be provided inside a main body 11 of a display device 1 according to an embodiment of the disclosure. The main body 11 may include a middle mold 14, a bottom chassis 15, and/or a rear cover 16.

As an example, the display apparatus 1 may include a display panel 20.The display panel 20 may be disposed on a front side of the main body 11. The display panel 20 may form a front portion of the display device 1. The display panel 20 may be provided to display the image I. As an example, the screen 12 may be formed on a front surface of the display panel 20.

As an example, the display panel 20 may have a substantially rectangular shape. As an example, the display panel 20 may have a shape in which a length of the horizontal side and a length of the vertical side are different from each other. That is, the display panel 20 may be provided to have a long side and a short side. The display panel 20 may be provided in a rectangular plate shape. However, the disclosure is not limited thereto, and the display panel 20 may be provided in the shape of a square plate in which the lengths of the long and short sides are approximately equal.

The display panel 20 may be provided in various sizes. The ratio between the long side and the short side of the display panel 20 is not limited to general cases such as 16:9 and 4:3, but may be provided at any ratio.

In the display apparatus 1 according to one or more embodiments, the display panel 20 may be composed of a non-self-luminous display such as a liquid crystal display (LCD).

A cable 20a configured to transmit image data to the display panel 20, and a display driver integrated circuit (DDI) (hereinafter referred to as ‘driver IC’) 30 configured to process digital image data and output an analog image signal may be provided at one side of the display panel 20.

The cable 20a may electrically connect a control assembly 50 and/or a power assembly 60 to the driver IC 30, and may also electrically connect the driver IC 30 to the display panel 20. The cable 20a may include a flexible flat cable or a film cable that is bendable.

The driver IC 30 may receive image data and power from the control assembly 50 and/or the power assembly 60 through the cable 20a. The driver IC 30 may provide the image data and driving current to the display panel 20 through the cable 20a.

In addition, the cable 20a and the driver IC 30 may be integrally implemented as a film cable, a chip on film (COF), or a tape carrier package (TCP). In other words, the driver IC 30 may be arranged on the cable 20a. However, the disclosure is not limited thereto, and the driver IC 30 may be arranged on the display panel 20.

The display apparatus 1 may include a backlight unit 100 configured to emit light toward the display panel 20. The backlight unit 100 may be disposed in the main body 11. The backlight unit 100 may be arranged at the rear of the display panel 20 to emit light toward the front where the display panel 20 is located. The display panel 20 may block or pass light emitted from the backlight unit 100. The backlight unit 100 may be a light source device.

The backlight unit 100 may include a point light source configured to emit monochromatic light or white light. The backlight unit 100 may refract, reflect, and scatter light to convert light, which is emitted from the point light source, into uniform surface light. The backlight unit 100 may refract, reflect, and scatter light emitted from the point light source, thereby emitting uniform surface light toward the front side.

The backlight unit 100 may include a light source module 1000. The light source module 1000 may generate and emit light. As an example, the light source module 1000 may be configured to emit monochromatic light or white light.

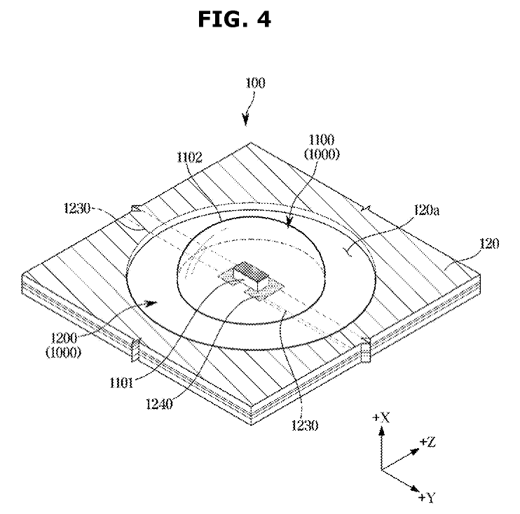

The light source module 1000 may include a plurality of light sources 1100 configured to emit light, and a light source substrate 1200 on which the plurality of light sources 1100 is mounted (refer to FIG. 4, etc.)

The backlight unit 100 may include a reflective sheet 120 provided to reflect light. The reflective sheet 120 may reflect light forward or in a direction close to the front. As an example, the reflective sheet 120 may be attached to a front surface of the light source module 1000. The reflective sheet 120 may be attached to a front surface of the light source substrate 1200.

As an example, in front of the reflective sheet 120, the light source module 1000 (e.g., the light source 1100 of the light source module 1000, refer to FIG. 4) may emit light in various directions. The light emitted from the light source module 1000 may not only be emitted toward a diffuser plate 130, which will be described later, but may also be emitted from the light source module 1000 toward the reflective sheet 120. The reflective sheet 120 may reflect the light, which is emitted toward the reflective sheet 120, toward the diffuser plate 130.

Further, while the light emitted from the light source module 1000 passes through various objects such as the diffuser plate 130 and an optical sheet 140, a portion of the light may be reflected from a surface of the diffuser plate 130 and the optical sheet 140. The reflective sheet 120 may reflect the light, which is reflected by the above-mentioned reason, forward again.

The backlight unit 100 may include the diffuser plate 130 provided to uniformly diffuse light. The diffuser plate 130 may be provided in front of the light source module 1000 and the reflective sheet 120. The diffuser plate 130 may evenly disperse the light emitted from the light source module 1000 and then emit the light forward.

The backlight unit 100 may include the optical sheet 140 provided to further improve the luminance and uniformity of the emitted light. The optical sheet 140 may be provided to refract and scatter light emitted from the front of the diffuser plate 130. As an example, the optical sheet 140 may include various types of sheets, such as a diffusion sheet, a prism sheet, a reflective polarizing sheet, and a quantum dot sheet.

The diffuser plate 130 and the optical sheet 140 may be optical members.

The display apparatus 1 may include the control assembly 50 configured to control the operation of the backlight unit 100 and the display panel 20, and the power assembly 60 configured to supply power to the backlight unit 100 and the display panel 20. The control assembly 50 and the power assembly 60 may be disposed in the main body 11.

The control assembly 50 may include a control circuit configured to control an operation of the display panel 20 and the backlight unit 100. The control circuit may process image data received from an external content source, transmit image data to the display panel 20, and transmit dimming data to the backlight unit 100.

The power assembly 60 may include a power circuit configured to supply power to the display panel 20 and the backlight unit 100 so as to allow the backlight unit 100 to emit surface light and to allow the display panel 20 to block or pass the light emitted from the backlight unit 100.

The control assembly 50 and the power assembly 60 may be implemented as a printed circuit board and various circuits mounted on the printed circuit board. As an example, the power circuit may include a capacitor, a coil, a resistance element, a processor, and a power circuit board on which the capacitor, the coil, the resistance element, and the processor are mounted. Further, the control circuit may include a memory, a processor, and a control circuit board on which the memory and the processor are mounted.

The display apparatus 1 may include a display case provided to support various components of the main body 11 of the display apparatus 1. In other words, various components of the main body 11 may be accommodated inside the display case. The display case may form the external appearance of the display apparatus 1.

As an example, the display case may support the display panel 20. As an example, the display case may support the backlight unit 100. As an example, the display case may support the control assembly 50. According to one or more embodiments, the display case may support the power assembly 60.

As an example, the display apparatus 1 may include a bottom chassis 15. The bottom chassis 15 may cover a rear side of the display panel 20. The bottom chassis 15 may be coupled to the middle mold 14. The bottom chassis 15 may support various components of the display apparatus 1, such as the backlight unit 100, the control assembly 50, and the power assembly 60.

The bottom chassis 15 may be formed to have a substantially flat plate shape, but is not limited thereto. The bottom chassis 15 may include a material having high thermal conductivity so as to dissipate heat generated from the light sources 1100 to the outside. As an example, the bottom chassis 15 may include a metal material such as aluminum or SUS, or a plastic material such as ABS.

The display apparatus 1 may include a middle mold 14. The middle mold 14 may be coupled to the bottom chassis 15. For example, the middle mold 14 may be hook-coupled to and/or mounted on the bottom chassis 15. The middle mold 14 may support the display panel 20) and/or the backlight unit 100. The middle mold 14 may form an edge portion of the display apparatus. For example, the middle mold 14 may be disposed along a rim of the bottom chassis 15 to support and fix at least some components of the backlight unit 100.

As an example, the display apparatus 1 may include a rear cover 16. The rear cover 16 may be disposed at a rear side of the bottom chassis 15 and may cover the bottom chassis 15 and various components mounted on the rear side of the bottom chassis 15 (e.g., the control assembly 50 and the power assembly 60).

The configuration of the display apparatus 1 described above with reference to FIG. 2 is only an example of the one or more embodiments for describing the display apparatus according to the disclosure, and the disclosure is not limited thereto.

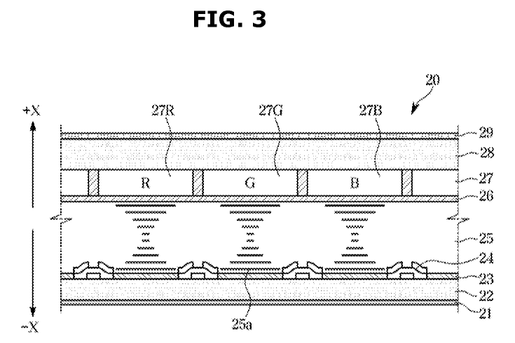

FIG. 3 is a cross-sectional view of a display panel of the display apparatus according an embodiment of the present disclosure.

Referring to FIG. 3, the display panel 20 included in the display apparatus 1 according to an embodiment of the disclosure may be composed of a liquid crystal display (LCD) panel, and configured to block or transmit light emitted from the backlight unit 100. The image I may be formed in front of the display panel 20 by an operation in which the display panel 20 blocks or transmits the light emitted from the backlight unit 100.

The front surface of the display panel 20 may form the screen 12 of the display apparatus 1 described above. The plurality of pixels P may be provided in the display panel 20. In the display panel 20, the plurality of pixels P may independently block or transmit light of the backlight unit 100, and the light transmitted through the plurality of pixels P may form the image I displayed on the screen 12.

For example, as shown in FIG. 3, the display panel 20 may include a first polarizing film 21, a first transparent substrate 22, a pixel electrode 23, a thin film transistor 24, a liquid crystal layer 25, a common electrode 26, a color filter 27, a second transparent substrate 28, and a second polarizing film 29.

The first transparent substrate 22 and the second transparent substrate 28 may fixedly support the pixel electrode 23, the thin film transistor 24, the liquid crystal layer 25, the common electrode 26, and the color filter 27. The first and second transparent substrates 22 and 28 may be formed of tempered glass or transparent resin.

The first polarizing film 21 and the second polarizing film 29 may be provided on the outside of the first and second transparent substrates 22 and 28.

Each of the first polarizing film 21 and the second polarizing film 29 may transmit a specific light beam and block other light beams. For example, the first polarizing film 21 may transmit a light beam having a magnetic field vibrating in a first direction and block other light beams. In addition, the second polarizing film 29 may transmit a light beam having a magnetic field vibrating in a second direction and block other light beams. In this case, the first direction and the second direction may be perpendicular to each other. Accordingly, a polarization direction of the light transmitted through the first polarizing film 21 and a vibration direction of the light transmitted through the second polarizing film 29 may be perpendicular to each other. As a result, generally, light may not pass through the first polarizing film 21 and the second polarizing film 29 at the same time.

The color filter 27 may be provided on an inner side of the second transparent substrate 28.

The color filter 27 may include a red filter 27R transmitting red light, a green filter 27G transmitting green light, and a blue filter 27B transmitting blue light. The red filter 27R, the green filter 27G, and the blue filter 27B may be disposed in parallel with each other. A region, in which the color filter 27 is formed, may correspond to the pixel P described above. A region, in which the red filter 27R is formed, may correspond to the red sub-pixel P_{R}, a region, in which the green filter 27G is formed, may correspond to the green sub-pixel P_{G}, and a region, in which the blue filter 27B is formed, may correspond to the blue sub-pixel P_{B}.

The pixel electrode 23 may be provided on an inner side of the first transparent substrate 22, and the common electrode 26 may be provided on an inner side of the second transparent substrate 28.

The pixel electrode 23 and the common electrode 26 may be formed of a metal material through which electricity is conducted, and the pixel electrode 23 and the common electrode 26 may generate an electric field to change the arrangement of liquid crystal molecules 25a forming the liquid crystal layer 25 to be described below.

The pixel electrode 23 and the common electrode 26 may be formed of a transparent material, and may transmit light incident from the outside. For example, the pixel electrode 23 and the common electrode 26 may include indium tin oxide (ITO), indium zinc oxide (IZO), silver nanowire (Ag nano wire), carbon nanotube (CNT), graphene, or poly (3,4-ethylenedioxythiophene) (PEDOT). The thin film transistor (TFT) 24 may be provided in an inner side of the second transparent substrate 28.

The TFT 24 may transmit or block a current flowing through the pixel electrode 23.For example, an electric field may be formed or removed between the pixel electrode 23 and the common electrode 26 in response to turning on (closing) or turning off (opening) the TFT 24.

The TFT 24 may be formed of poly-silicon, and may be formed by semiconductor processes, such as lithography, deposition, and ion implantation.

The liquid crystal layer 25 may be formed between the pixel electrode 23 and the common electrode 26, and the liquid crystal layer 25 may be filled with the liquid crystal molecules 25a.

Liquid crystals represent an intermediate state between a solid (crystal) and a liquid. Most of the liquid crystal materials are organic compounds, and the molecular shape is in the shape of an elongated rod, and the orientation of molecules is in an irregular state in one direction, but in a regular state in other directions. As a result, the liquid crystal has both the fluidity of the liquid and the optical anisotropy of the crystal (solid).

In addition, liquid crystals also exhibit optical properties according to changes in an electric field. In the liquid crystal, the orientation of molecules forming the liquid crystal may change according to a change in an electric field. When an electric field is generated in the liquid crystal layer 25, the liquid crystal molecules 25a of the liquid crystal layer 25 may be disposed along the direction of the electric field. When the electric field is not generated in the liquid crystal layer 25, the liquid crystal molecules 25a may be disposed irregularly or disposed along an alignment layer (not shown). As a result, the optical properties of the liquid crystal layer 25 may vary depending on the presence or absence of the electric field passing through the liquid crystal layer 25.

The structure of the display panel 20 described above with reference to FIG. 3 is only an example of a structure of the display panel of the display apparatus according to an embodiment of the disclosure, and the disclosure is not limited thereto.

FIG. 4 is an enlarged view illustrating a backlight unit of a display apparatus according to an embodiment of the present disclosure.

Referring to FIG. 4, the display apparatus 1 according to one embodiment of the disclosure may include the plurality of light sources 1100 and the light source substrate 1200 on which the light sources 1100 are mounted. The plurality of light sources 1100 and the light source substrate 1200 may form the light source module 1000 of the backlight unit 100.

FIG. 4 illustrates one light source 1100 among the plurality of light sources 1100 included in the light source module 1000, and a description of a structure and function of the light source 1100 described below with reference to FIG. 4 may be commonly applied to each of the plurality of light sources 1100.

The light source 1100 may be configured to emit light toward the display panel 20. The light source 1100 may employ an element configured to emit monochromatic light (light of a specific wavelength, e.g., blue light) or white light (e.g., light of a mixture of red light, green light, and blue light) in various directions when power is supplied thereto. For example, the light source 1100 may include a light emitting diode (LED).

The light source substrate 1200 may fix the plurality of light sources 1100 to prevent a change in the position of the light source 1100. In addition, the light source substrate 1200 may be electrically connected to the light source 1100. The light source substrate 1200 may supply power, which is for the light source 1100 to emit light, to each light source 1100.

The light source substrate 1200 may fix the plurality of light sources 1100 and may be configured with synthetic resin or tempered glass or a printed circuit board (PCB) on which a conductive power supply line for supplying power to the light source 1100 is formed.

The light source 1100 may be disposed on the front surface of the light source substrate 1200. For example, the front surface of the light source substrate 1200 may refer to one surface of the light source substrate 1200 facing the display panel 20. The light source 1100 may be mounted on the light source substrate 1200 to face forward and emit light forward.

The reflective sheet 120 may be disposed in front of the light source substrate 1200. For example, the reflective sheet 120 may be coupled to the front surface of the light source substrate 1200. In this case, the reflective sheet 120 may include a plurality of through holes 120a formed at positions corresponding to each of the plurality of light sources 1100 of the light source module 1000. As shown in FIG. 4, the light source 1100 may pass through the through hole 120a and protrude toward the front of the reflective sheet 120. As a result, the light source 1100 and a portion of the light source substrate 1200 may be exposed toward the front of the reflective sheet 120 through the through hole 120a. With this configuration, the light source 1100 may emit light in front of the reflective sheet 120. The through hole (120a) may be an LED hole (120a).

The reflective sheet 120 may reflect light, which is emitted from the light source 1100 toward the reflective sheet 120, toward the diffuser plate 130.

A process, in which the light emitted from the plurality of light sources 1100 or the light reflected by the reflective sheet 120 travels toward the display panel 20, is as described above.

Hereinafter a structure of the light source 1100 and the light source substrate 1200 will be described.

The light source 1100 may include a light emitting diode 1101. The light emitting diode 1101 may include a P-type semiconductor and an N-type semiconductor for emitting light by recombination of holes and electrons. In addition, the light emitting diode 1101 may be provided with a pair of electrodes for supplying hole and electrons to the P-type semiconductor and the N-type semiconductor, respectively.

The light emitting diode 1101 may be configured to convert electrical energy into optical energy. In other words, the light emitting diode 1101 may emit light having a maximum intensity at a predetermined wavelength based on the supplied power. For example, the light emitting diode 1101 may emit blue light having a peak value at a wavelength indicating blue color (e.g., a wavelength between 430 nm and 495 nm).

As an example, a multilayer reflective structure, in which a plurality of insulation layers having different refractive indices is alternately laminated, may be provided on the front surface of the light emitting diode 1101. For example, the multilayer reflective structure may be provided with a Distributed Bragg Reflector (DBR).

As an example, the light emitting diode 1101 may be directly attached to the light source substrate 1200 in a Chip On Board (COB) method. In other words, the light source 1100 may include the light emitting diode 1101 to which a light emitting diode chip or a light emitting diode die is directly attached to the light source substrate 1200 without an additional packaging.

The light source module 1000 may be manufactured in such a way that the flip-chip type light emitting diode 1101 is attached to the light source substrate 1200 in a chip-on-board method. Accordingly, it is possible to reduce the size of the light source 1100.

The light source substrate 1200 may include a power supply line 1230 provided to supply power to the light source 1100. The power supply line 1230 may be provided to supply an electrical signal and/or power from the control assembly 50 and/or the power assembly 60 to the light source 1100. As an example, the power supply line 1230 may be provided to supply power to the flip chip type light emitting diode 1101.

As an example, the light source substrate 1200 may be formed by alternately laminating an insulation layer that is non-conductive and a conduction layer that is conductive.

A line or pattern, through which power and/or electrical signals pass, may be formed on the conduction layer. The conduction layer may be formed of various materials having an electrical conductivity. For example, the conduction layer may be formed of various metal materials, such as copper (Cu), tin (Sn), aluminum (Al), or an alloy thereof. The power supply line 1230 may be implemented by the line or pattern formed on the conduction layer of the light source substrate 1200.

A dielectric of the insulation layer of the light source substrate 1200 may insulate between lines or patterns of the conduction layer. The insulation layer may be formed of a dielectric for electrical insulation, such as a multipurpose glass epoxy laminate that features flame-retardant properties (FR-4).

As an example, a protection layer configured to prevent or suppress damages caused by an external impact and/or damages caused by a chemical action (e.g., corrosion, etc.) and/or damages caused by an optical action, to the light source substrate 1200 may be formed on an outer surface of the light source substrate 1200. As an example the protection layer of the light source substrate 1200 may include a photo solder resist (PSR).

The power supply line 1230 may be covered by the protection layer of the light source substrate 1200, so as to be prevented from being exposed to the outside.

As an example, the light source substrate 1200 may include a power supply pad 1240 provided to be electrically connected to the power supply line 1230 to supply power to the flip chip type light emitting diode 1101. The power supply line 1230 may be electrically connected to the light emitting diode 1101 through the power supply pad 1240.

As an example, a window may be formed in the protection layer of the light source substrate 1200 to expose a portion of the power supply line 1230 to the outside. The power supply pad 1240 may be electrically connected to a portion of the power supply line 1230 exposed to the outside of the light source substrate 1200.

As an example, various electrically conductive adhesive materials such as solder and electrically conductive epoxy adhesives may be applied between the electrode of the light emitting diode 1101 and the power supply pad 1240.

The light source 1100 may include an optical dome 1102. The optical dome 1102 may cover the light emitting diode 1101. The optical dome 1102 may prevent or suppress damages to the light emitting diode 1101 caused by an external mechanical action and/or damage to the light emitting diode 1101 caused by a chemical action.

The optical dome 1102 may have a dome shape formed in such a way that a sphere is cut into a surface not including the center thereof, or may have a hemispherical shape in such a way that a sphere is cut into a surface including the center thereof. A vertical cross section of the optical dome 1102 may be a bow shape or a semicircle shape.

The optical dome 1102 may be formed of silicone or epoxy resin. As an example, the molten silicon or epoxy resin may be discharged onto the light emitting diode 1101 through a nozzle, and the discharged silicon or epoxy resin may be cured, thereby forming the optical dome 1102.

The optical dome 1102 may be optically transparent or translucent. Light emitted from the light emitting diode 1101 may be emitted to the outside by passing through the optical dome 1102.

In this case, as an example, the dome-shaped optical dome 1102 may refract light like a lens. For example, light emitted from the light emitting diode 1101 may be refracted by the optical dome 1102 and thus may be dispersed.

The structure of the light source module 1000 such as the light source 1100 and the light source substrate 1200 described with reference to FIG. 4 is only an example of the structure of the light source module of the display apparatus according to an embodiment of the disclosure and the disclosure is not limited thereto.

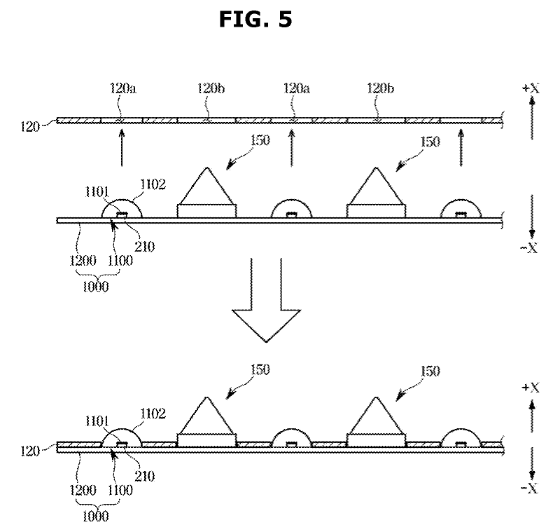

FIG. 5 is a schematic diagram illustrating the coupling of a light source and a reflective sheet in a display apparatus according to an embodiment of the present disclosure.

Referring to FIG. 5, a plurality of supporter holes 120b may be formed in the reflective sheet 120 at positions corresponding to supporters 150. The supporters 150 may protrude through the supporter holes 120b to support the diffuser plate 130 and/or the optical sheet 140. The supporters 150 may be positioned in the supporter holes 120b.

For example, as shown in the upper portion of FIG. 5, during the assembly process of the reflective sheet 120 and the light source module 1000, a plurality of light sources 1100 of the light source module 1000 are inserted into the plurality of light source through-holes 120a formed in the reflective sheet 120, and the supporters 150 are inserted into the supporter holes 120b. As a result, as shown in the lower portion of FIG. 5, the substrate 1200 of the light source module 1000 is positioned behind the reflective sheet 120, but the plurality of light sources 1100 of the light source module 1000 may be positioned in front of the reflective sheet 120. The plurality of light sources 1100 may emit light at the front side of the reflective sheet 120.

The plurality of light sources 1100 may emit light in various directions at the front side of the reflective sheet 120. Light may be emitted not only from the light source 1100 toward the diffuser plate 130 but also from the light source 1100 toward the reflective sheet 120, and the reflective sheet 120 may reflect the light emitted toward the reflective sheet 120 to be directed toward the diffuser plate 130.

Light emitted from the light source 1100 passes through various objects such as the diffuser plate 130 and the optical sheet 140. When light passes through the diffuser plate 130 and the optical sheet 140, a portion of the incident light is reflected from the surfaces of the diffuser plate 130 and the optical sheet 140. The reflective sheet 120 may reflect light reflected by the diffuser plate 130 and the optical sheet 140.

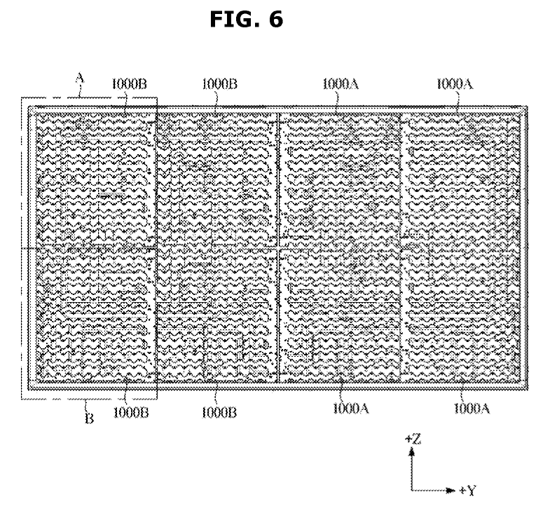

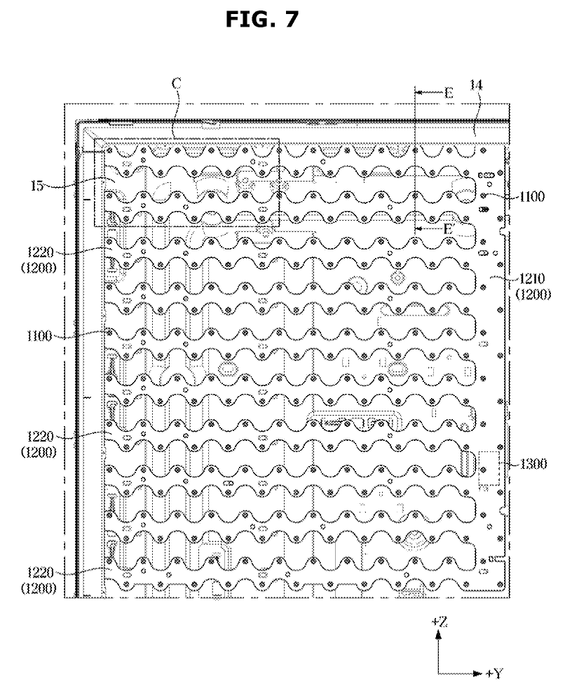

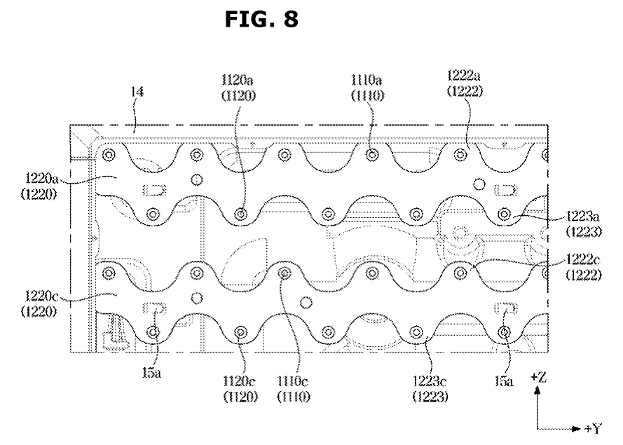

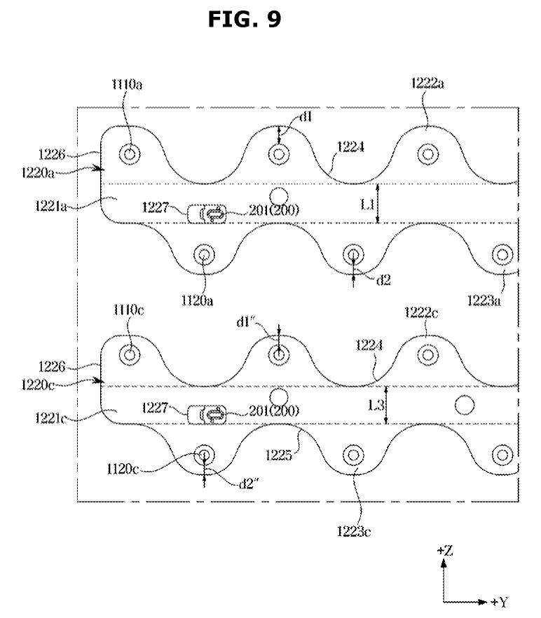

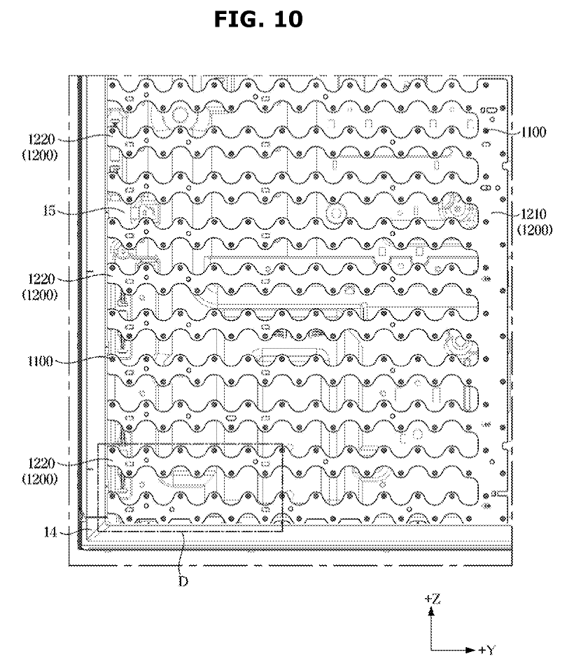

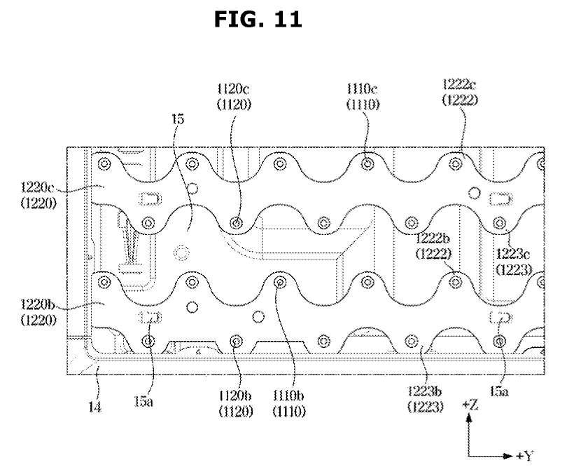

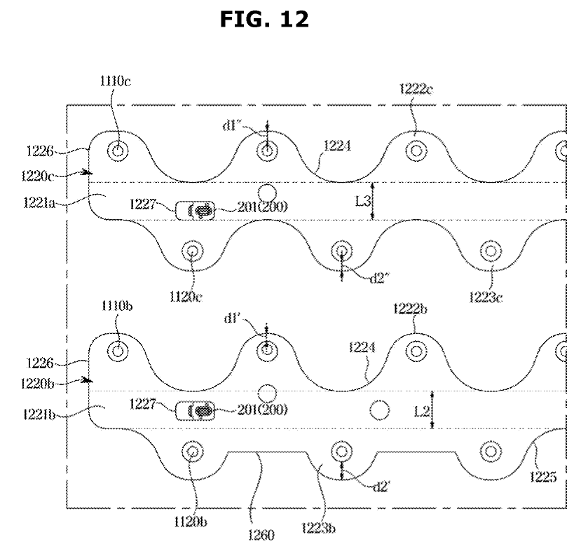

FIG. 6 is a view illustrating a light source substrate and a bottom chassis of a display apparatus according to an embodiment of the present disclosure. FIG. 7 is an enlarged view illustrating a light source substrate and a bottom chassis of a display apparatus according to an embodiment of the present disclosure. FIG. 8 is an enlarged view illustrating a portion of a light source substrate of a display apparatus according to an embodiment of the present disclosure. FIG. 9 is an enlarged view illustrating a portion of a light source substrate of a display apparatus according to an embodiment of the present disclosure. FIG. 10 is an enlarged view illustrating a light source substrate and a bottom chassis of a display apparatus according to an embodiment of the present disclosure. FIG. 11 is an enlarged view illustrating a portion of a light source substrate of a display apparatus according to an embodiment of the present disclosure. FIG. 12 is an enlarged view illustrating a portion of a light source substrate of a display apparatus according to an embodiment of the present disclosure.

FIG. 7 is an enlarged view of region A of the display apparatus shown in FIG. 6. FIG. 8 is an enlarged view of region C of the display apparatus shown in FIG. 7. FIG. 9 is a view of the display apparatus shown in FIG. 8 with the bottom chassis omitted. FIG. 10 is an enlarged view of region B of the display apparatus shown in FIG. 6. FIG. 11 is an enlarged view of region D of the display apparatus shown in FIG. 10. FIG. 12 is a view of the display apparatus shown in FIG. 11 with the bottom chassis omitted.

Referring to FIGS. 6 to 12, the display apparatus 1 according to an embodiment of the disclosure may include a plurality of light source modules 1000.

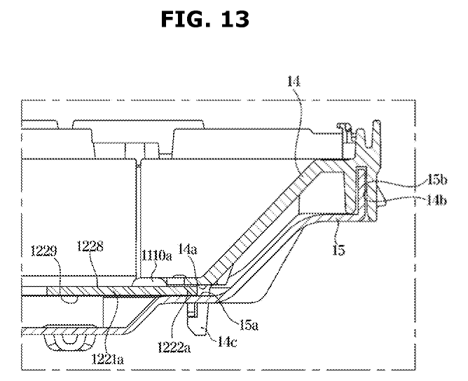

The plurality of light source modules 1000 may be disposed in front of the bottom chassis 15. Each of the plurality of light source modules 1000 may be mounted on the bottom chassis 15. For example, the plurality of light source modules 1000 may be fixed to the bottom chassis 15 by fixers 201 and the middle mold 14, and may be supported by the bottom chassis 15 (refer to FIGS. 13 to 15).

As an example, the plurality of light source modules 1000 may be formed in shapes corresponding to each other. In other words, each of the plurality of light source modules 1000 may have substantially the same structure.

For example, among the plurality of light source modules 1000, a light source module 1000A positioned on the right side (in the +Y direction) of the display apparatus 1 and a light source module 1000B positioned on the left side (in the -Y direction) of the display apparatus 1 may be arranged to be opposite to each other in the vertical direction and the horizontal direction (for example, arranged in a state rotated 180 degrees with respect to the X-axis). With such an arrangement, the plurality of light source modules 1000 may be arranged symmetrically with respect to the horizontal center of the display apparatus 1, and luminance may be uniformly provided on both sides with respect to the horizontal center of the display apparatus 1.

Since the plurality of light source modules 1000 are designed to have substantially the same shape as described above, waste of components may be prevented and manufacturing process efficiency may be improved, thereby reducing manufacturing costs.

However, the preset disclosure is not limited thereto, and at least some of the plurality of light source modules 1000 may be formed to have different shapes from each other.

Although FIG. 6 illustrates an example in which the display apparatus 1 includes eight light source modules 1000, the number of light source modules 1000 included in the display apparatus 1 is not limited to that shown in FIG. 6. As an example, the number of light source modules 1000 included in the display apparatus 1 may be greater or smaller than that shown in FIG. 6. Alternatively, the display apparatus 1 may include one light source module 1000 formed as one part.

Hereinafter, the structure of one light source module 1000 among the plurality of light source modules 1000 will be described in detail. In one embodiment, the structure of the one light source module 1000 described below may be correspondingly applied to each of the plurality of light source modules 1000.

The light source module 1000 of the display apparatus 1 according to an embodiment of the disclosure may include a plurality of substrate bars 1220.

The substrate bar 1220 may constitute at least a portion of the light source substrate 1200 described above, and may be a component including a printed circuit board having a shape extending in one direction.

At least some of the plurality of light sources 1100 may be mounted on the plurality of substrate bars 1220. The at least some of the plurality of light sources 1100 may be mounted on front surfaces of the plurality of substrate bars 1220. Here, the front surfaces of the plurality of substrate bars 1220 may refer to surfaces of the plurality of substrate bars 1220 facing toward the display panel 20.

The plurality of substrate bars 1220 may be composed of printed circuit boards on which the light sources 1100 are mounted and the above-described power supply lines 1230 are provided.

The plurality of substrate bars 1220 may be arranged to be spaced apart from each other. The plurality of substrate bars 1220 may be arranged to be spaced apart from each other along one direction Z. As an example, the one direction Z in which the plurality of substrate bars 1220 are spaced apart from each other may be substantially parallel to the vertical direction (for example, up-down direction) of the display apparatus 1. The plurality of substrate bars 1220 may be arranged to be parallel to each other at spaced positions. The direction in which the plurality of substrate bars 1220 are arranged may be a second direction Z or a third direction -Z.

Each of the plurality of substrate bars 1220 may be formed to have substantially a bar shape. For example, each of the plurality of substrate bars 1220 may have a width in the second direction Z or the third direction -Z, and may extend long in a direction Y different from the second direction Z and the third direction -Z. The direction in which the plurality of substrate bars 1220 extend may be the first direction Y. For example, each of the plurality of substrate bars 1220 may have a shape in which a length in the first direction Y is longer than a width in the second direction Z or the third direction -Z.

As an example, the width direction of each of the plurality of substrate bars 1220 may be substantially parallel to the vertical direction (for example, up-down direction) of the display apparatus 1. As an example, the direction in which each of the plurality of substrate bars 1220 extends may be substantially parallel to the horizontal direction (for example, left-right direction) of the display apparatus 1.

As an example, the direction in which each of the plurality of substrate bars 1220 extends may be parallel to a long-side direction of the display apparatus 1. As an example, the width direction of each of the plurality of substrate bars 1220 may be parallel to a short-side direction of the display apparatus 1.

As an example, the direction in which the plurality of substrate bars 1220 are spaced apart from each other may be parallel to the width direction of each substrate bar 1220. In other words, the plurality of substrate bars 1220 may be arranged to be spaced apart from each other along the first direction Z, which is the width direction of each.

Each of the plurality of substrate bars 1220 may extend in a direction different from the direction in which the plurality of substrate bars 1220 are spaced apart from each other. For example, each of the plurality of substrate bars 1220 may extend in a direction (the Y direction) that is perpendicular to the direction (the Z direction) in which the plurality of substrate bars 1220 are spaced apart from each other. For example, the first direction and the second and third directions may be directions perpendicular to each other. In addition, for example, the second direction and the third direction may be directions parallel to each other.

Alternatively, the direction in which the plurality of substrate bars 1220 are spaced apart from each other and the direction in which each of the plurality of substrate bars 1220 extends may have a predetermined angle that is not exactly 90 degrees.

As an example, the plurality of substrate bars 1220 may be arranged such that the distance spaced apart in the second direction Z from each other is uniform. In other words, the distance in the second direction Z between a pair of adjacent substrate bars 1220 among the plurality of substrate bars 1220 may all be substantially the same. As a result, the uniformity of luminance of the display apparatus 1 may be improved.

As an example, the plurality of substrate bars 1220 may be formed to have shapes corresponding to each other. As an example, the plurality of substrate bars 1220 may have corresponding widths in the second direction (the Z direction). As an example, the plurality of substrate bars 1220 may have corresponding lengths extending in the first direction (the Y direction). As an example, the plurality of substrate bars 1220 may be formed to have corresponding sizes.

As an example, each of the plurality of substrate bars 1220 may be mounted on the bottom chassis 15. As each of the plurality of substrate bars 1220 is mounted on and fixed to the bottom chassis 15, the plurality of light sources 1100 mounted on the plurality of substrate bars 1220 may be stably arranged at designed positions.

A reflective sheet 120 may be attached to the front surface of each of the plurality of substrate bars 1220.

The light source module 1000 of the display apparatus 1 may include a substrate body 1210. The substrate body 1210 may constitute a portion of the above-described light source substrate 1200, and may be a component including a printed circuit board.

The plurality of substrate bars 1220 may be connected to the substrate body 1210. The plurality of substrate bars 1220 may be supported by the substrate body 1210. As an example, the plurality of substrate bars 1220 may be connected to one side of the substrate body 1210.

The plurality of substrate bars 1220 may extend from the substrate body 1210. As an example, each of the plurality of substrate bars 1220 may extend from the substrate body 1210 in the first direction Y. As an example, each of the plurality of substrate bars 1220 may extend from one side of the substrate body 1210 in the first direction Y.

As an example, the substrate body 1210 may extend along the second direction Z. As an example, the substrate body 1210 may have a shape in which a length in the second direction Z is longer than a width in the first direction Y. In this case, as the substrate body 1210 extends along the direction in which the plurality of substrate bars 1220 are arranged, a structure in which a larger number of substrate bars 1220 are connected may be provided. In addition, in this case, the plurality of substrate bars 1220 may extend from one side in the first direction Y, which is the width direction (a relatively short direction), of the substrate body 1210, thereby having shapes extending longer.

As an example, the substrate body 1210 may be mounted on the bottom chassis 15. In addition, the substrate body 1210 may be disposed between the middle mold 14 and the bottom chassis 15 so as to be fixed within the display apparatus 1. As the substrate body 1210 maintains a fixed position, the plurality of light sources 1100 mounted on the substrate body 1210 may be stably arranged at designed positions. In addition, the plurality of substrate bars 1220 connected to the substrate body 1210 may be more stably supported by the substrate body 1210.

As an example, some of the plurality of light sources 1100 may be mounted on the substrate body 1210. Some of the plurality of light sources 1100 may be mounted on a front surface of the substrate body 1210. Here, the front surface of the substrate body 1210 may refer to a surface of the substrate body 1210 facing toward the display panel 20.

The substrate body 1210 may be composed of a printed circuit board on which the light source 1100 is mounted and the above-described power supply line 1230 is provided.

A reflective sheet 120 may be attached to the front surface of the substrate body 1210. As an example, an integral reflective sheet 120 may be attached to the front surfaces of the substrate body 1210 and the plurality of substrate bars 1220. In this case, the uniformity of luminance by light reflected by the reflective sheet 120 may be improved, and a process of attaching the reflective sheet 120 to the front surfaces of the substrate body 1210 and the plurality of substrate bars 1220 may be simplified. However, the preset disclosure is not limited thereto, and a plurality of separate reflective sheets 120 may be attached to the front surfaces of the substrate body 1210 and the plurality of substrate bars 1220.

The display apparatus 1 may include a connector 1300. The connector 1300 may be electrically connected to the plurality of light sources 1100. The connector 1300 may be electrically connected to the light source substrate 1200. The connector 1300 may be electrically connected to various electronic components mounted on the light source substrate 1200, such as the plurality of light sources 1100, along the power supply line 1230 provided on the light source substrate 1200. As a result, the connector 1300 may transmit electrical signals transmitted from the control assembly 50 to various electronic components mounted on the light source substrate 1200, such as the plurality of light sources 1100, and may transmit power supplied from the power assembly 60 to various electronic components mounted on the light source substrate 1200, such as the plurality of light sources 1100. In other words, the light source module 1000 may be electrically connected to the control assembly 50 and/or the power assembly 60 through the connector 1300.

As an example, the connector 1300 may be mounted on the substrate body 1210. For example, the connector 1300 may be mounted on a rear surface of the substrate body 1210 facing the bottom chassis 15.

Since the reflective sheet 120 may be attached to the front surface of the substrate body 1210 as described above, when the connector 1300 is mounted on the front surface of the substrate body 1210, a portion of the reflective sheet 120 at a position corresponding to the mounting position of the connector 1300 may interfere with the connector 1300, which may degrade the uniformity of luminance of the display apparatus 1. On the contrary, in an embodiment of the disclosure, as the connector 1300 is mounted on the rear surface of the substrate body 1210, a decrease in luminance uniformity of the display apparatus 1 may be prevented.

As an example, the substrate body 1210 and the plurality of substrate bars 1220 may be integrally formed. In other words, the substrate body 1210 and the plurality of substrate bars 1220 may be connected to each other to form an integral light source substrate 1200. The light source substrate 1200 may be composed of an integral printed circuit board including the substrate body 1210 and the plurality of substrate bars 1220. Alternatively, the substrate body 1210 and the plurality of substrate bars 1220 may be separate parts that are connected through an assembling process.

The structure of the light source module 1000, such as the substrate body 1210 and the substrate bar 1220 described above, is only an example, and the disclosure is not limited thereto.

For example, each of the plurality of substrate bars 1220 may extend in the -Y direction from the substrate body 1210, or the plurality of substrate bars 1220 may extend in the +Y direction from the substrate body 1210.

In addition, although an embodiment in which the substrate body 1210 extends in the vertical direction (Z direction) of the display apparatus 1 is shown, the preset disclosure is not limited thereto, and for example, the substrate body 1210 may extend in the horizontal direction (Y direction).

In addition, although an embodiment in which each of the plurality of substrate bars 1220 extends in the horizontal direction (Y direction) from one side of the substrate body 1210 in the horizontal direction (Y direction) is shown, the preset disclosure is not limited thereto, and for example, each of the plurality of substrate bars 1220 may extend in the vertical direction (Z direction) from one side of the substrate body 1210 in the vertical direction (Z direction). In this case, the plurality of substrate bars 1220 may be arranged to be spaced apart from each other in the horizontal direction (Y direction).

In addition, unlike described above, the second direction, which is the width direction of each of the plurality of substrate bars 1220, or the second direction in which the plurality of substrate bars 1220 are spaced apart from each other, or the second direction in which the substrate body 1210 extends, or the first direction in which each of the plurality of substrate bars 1220 extends may not be parallel to either the vertical direction (Z direction) or the horizontal direction (Y direction) of the display apparatus 1.

However, for convenience of description, the following description will be made based on an embodiment in which the second direction is parallel to the vertical direction (Z direction) of the display apparatus 1 and the first direction is parallel to the horizontal direction (Y direction) of the display apparatus 1.

Hereinafter, the position and structure of one substrate bar 1220 among the plurality of substrate bars 1220 will be described. The structure of the substrate bar 1220 described below may be correspondingly applied to the structure of each of the plurality of substrate bars 1220.

The substrate bar 1220 may be disposed between the middle mold 14 and the bottom chassis 15 in one direction. As an example, at least a portion of the substrate bar 1220 may be disposed between the middle mold 14 and the bottom chassis 15 in the front-rear direction. Along the front-rear direction, the middle mold 14, the substrate bar 1220, and the bottom chassis 15 may be sequentially arranged.

The substrate bar 1220 may include a central extension portion 1221 extending in one direction and protruding portions 1222 and 1223 protruding from the central extension portion 1221. The central extension portion 1221 and the protruding portions 1222 and 1223 may each form a portion of the light source substrate 1200 as a part of the substrate bar 1220.

The central extension portion 1221 may extend in the first direction (e.g., Y direction and/or -Y direction). The width direction of the central extension portion 1221 may be parallel to the second and third directions (e.g., Z direction and/or -Z direction). The central extension portion 1221 may have a shape in which the extension length in the first direction (e.g., Y direction) is longer than the width in the second direction (e.g., Z direction).

The central extension portion 1221 may be provided in a central region of the substrate bar 1220. The central extension portion 1221 may include a region passing through the center of the substrate bar 1220 and extending in the first direction (e.g., Y direction).

As an example, the central extension portion 1221 may include a substantially rectangular bar-shaped region.

The substrate bar 1220 may include a plurality of first protruding portions 1222 protruding to one side (first side) of the central extension portion 1221. Each of the plurality of first protruding portions 1222 may protrude from one side of the central extension portion 1221 in the second direction (e.g., Z direction). Each of the plurality of first protruding portions 1222 may extend from the central extension portion 1221 in the second direction (e.g., Z direction). As an example, each of the plurality of first protruding portions 1222 may extend upward from an upper side of the central extension portion 1221.

As an example, the first protruding portion 1222 may be integrally formed by being connected to the central extension portion 1221.

The plurality of first protruding portions 1222 may be arranged along the first direction (e.g., Y direction). As an example, the plurality of first protruding portions 1222 may be arranged such that the positions in the second direction Z (in other words, the vertical height of the display apparatus 1) correspond to each other.

As an example, the plurality of first protruding portions 1222 may be arranged at uniform intervals along the first direction (e.g., Y direction).

As an example, the plurality of first protruding portions 1222 may be formed to have shapes corresponding to each other. As an example, the length by which each of the plurality of first protruding portions 1222 protrudes from the central extension portion 1221 in the second direction (e.g., Z direction) may correspond to each other.

Some of the plurality of light sources 1100 mounted on the substrate bar 1220 may be mounted on the plurality of first protruding portions 1222. Hereinafter, the light source mounted on each of the plurality of first protruding portions 1222 is referred to as a first -side light source 1110. As an example, a single first -side light source 1110 may be mounted on a single first protruding portion 1222, but the preset disclosure is not limited thereto. The first -side light source 1110 may be a first light source 1110.

The plurality of first -side light sources 1110 may be disposed at positions spaced apart from the central extension portion 1221 in the second direction (Z direction). The plurality of first -side light sources 1110 may be arranged to be biased upward from the central extension portion 1221.

The plurality of first -side light sources 1110 may be arranged along the first direction Y direction. As an example, the plurality of first -side light sources 1110 may be arranged such that the positions in the second direction Z correspond to each other.

As an example, the plurality of first -side light sources 1110 may be arranged at uniform intervals along the first direction (Y direction).

The substrate bar 1220 may include a plurality of second protruding portions 1223 protruding to the other side (second side) of the central extension portion 1221. Each of the plurality of second protruding portions 1223 may protrude from the other side of the central extension portion 1221 in the second direction (Z direction). Here, the other side of the central extension portion 1221 refers to a side different from one side of the central extension portion 1221 from which the first protruding portion 1222 protrudes.

Each of the plurality of second protruding portions 1223 may extend from the central extension portion 1221 in the second direction (Z direction). As an example, each of the plurality of second protruding portions 1223 may extend downward from the lower side of the central extension portion 1221.

As an example, the second protruding portion 1223 may be integrally formed by being connected to the central extension portion 1221.

The plurality of second protruding portions 1223 may be arranged along the first direction (Y direction). As an example, the plurality of second protruding portions 1223 may be arranged such that the positions in the second direction Z (for example, the vertical height of the display apparatus 1) correspond to each other.

As an example, the plurality of second protruding portions 1223 may be arranged at uniform intervals along the first direction (Y direction).

As an example, the plurality of second protruding portions 1223 may be formed to have shapes corresponding to each other. As an example, the length by which each of the plurality of second protruding portions 1223 protrudes from the central extension portion 1221 in the second direction (Z direction) may correspond to each other.

Some of the plurality of light sources 1100 mounted on the substrate bar 1220 may be mounted on the plurality of second protruding portions 1223. Hereinafter, the light source mounted on each of the plurality of second protruding portions 1223 is referred to as a second -side light source 1120. As an example, a single second -side light source 1120 may be mounted on a single second protruding portion 1223, but the preset disclosure is not limited thereto. The second -side light source 1120 may be a second light source 1120.

The plurality of second -side light sources 1120 may be disposed at a position spaced apart from the central extension portion 1221 in the second direction Z direction. The plurality of second -side light sources 1120 may be arranged to be biased downward from the central extension portion 1221.

The plurality of second -side light sources 1120 may be arranged along the first direction Y direction. As an example, the plurality of second -side light sources may be arranged such that the positions in the second direction Z correspond to each other.

As an example, the plurality of second -side light sources 1120 may be arranged at uniform intervals along the first direction Y direction.

For example, the first -side light source 1110 and the second -side light source 1120 may be provided in the same number.

Here, some regions of the central extension portion 1221 from which the plurality of first protruding portions 1222 protrude and other regions of the central extension portion 1221 from which the plurality of second protruding portions 1223 extend may be arranged to alternate along the first direction (Y direction). In other words, the first protruding portion 1222 and the second protruding portion 1223 may be arranged to alternate with each other. In a single substrate bar 1220, the plurality of first protruding portions 1222 and the plurality of second protruding portions 1223 may be arranged not to be aligned with each other in the second direction Z.

With such a configuration, the first -side light source 1110 and the second -side light source 1120 may be arranged to alternate with each other along the first direction (Y direction). In a single substrate bar 1220, the plurality of light sources 1100 may be arranged such that the first -side light source 1110 disposed on one side in the second direction Z and the second -side light source 1120 disposed on the other side alternate with each other along the first direction (Y direction), thereby improving the uniformity of luminance by the plurality of light sources 1100. In other words, in a single substrate bar 1220, the plurality of light sources 1100 may be arranged in a zigzag manner. As an example, the first -side light source 1110 and the second -side light source 1120 may be arranged in a zigzag manner.

As the plurality of light sources 1100 are arranged as described above on each substrate bar 1220, the distance between adjacent light sources 1100 in a pair of adjacent substrate bars 1220 among the plurality of substrate bars 1220 may be reduced, and the luminance and luminance uniformity of the display apparatus 1 may be improved.

The substrate bar 1220 may include a plurality of first recess portions 1224. Each of the plurality of first recess portions 1224 may be formed between a pair of adjacent first protruding portions 1222 among the plurality of first protruding portions 1222.

The plurality of first recess portions 1224 may be provided on one side of the central extension portion 1221 in the second direction Z. As an example, the plurality of first recess portions 1224 may be provided on an upper side of the central extension portion 1221.

The plurality of first recess portions 1224 may be formed to be concavely recessed toward the inner side of the central extension portion 1221 relative to the plurality of first protruding portions 1222.

The plurality of first recess portions 1224 may be arranged along the first direction (Y direction). As an example, the plurality of first recess portions 1224 may be arranged such that the positions in the second direction Z (in other words, the vertical height of the display apparatus 1) correspond to each other.

As an example, the plurality of first recess portions 1224 may be arranged at uniform intervals along the first direction (Y direction).

As an example, the plurality of first recess portions 1224 may be formed to have shapes corresponding to each other.

The substrate bar 1220 may include a plurality of second recess portions 1225. Each of the plurality of second recess portions 1225 may be formed between a pair of adjacent second protruding portions 1223 among the plurality of second protruding portions 1223.

The plurality of second recess portions 1225 may be provided on the other side of the central extension portion 1221 in the second direction Z. Here, the other side of the central extension portion 1221 refers to a side different from one side of the central extension portion 1221 in which the first recess portion 1224 is provided. As an example, the plurality of second recess portions 1225 may be provided on a lower side of the central extension portion 1221.

The plurality of second recess portions 1225 may be formed to be concavely recessed toward the inner side of the central extension portion 1221 relative to the plurality of second protruding portions 1223.

The plurality of second recess portions 1225 may be arranged along the first direction (Y direction). As an example, the plurality of second recess portions 1225 may be arranged such that the positions in the second direction Z (in other words, the vertical height of the display apparatus 1) correspond to each other.

As an example, the plurality of second recess portions 1225 may be arranged at uniform intervals along the first direction (Y direction).

As an example, the plurality of second recess portions 1225 may be formed to have shapes corresponding to each other.

Some regions of the central extension portion 1221 on one side in which the plurality of first recess portions 1224 are provided and other regions of the central extension portion 1221 on the other side in which the plurality of second recess portions 1225 are provided may be arranged to alternate along the first direction (Y direction). As an example, the first recess portion 1224 and the second recess portion 1225 may be arranged to alternate with each other. In a single substrate bar 1220, the plurality of first recess portions 1224 and the plurality of second recess portions 1225 may be arranged not to be aligned with each other in the second direction Z.

As an example, each of the plurality of first protruding portions 1222 may be arranged parallel to one second recess portion 1225, which is closest among the plurality of second recess portions 1225, in the second direction Z. As an example, the plurality of first protruding portions 1222 and the plurality of second recess portions 1225 may be arranged parallel to each other in the second direction Z.

In addition, as an example, each of the plurality of second protruding portions 1223 may be arranged parallel to one first recess portion 1224, which is closest among the plurality of first recess portions 1224, in the second direction Z. As an example, the plurality of second protruding portions 1223 and the plurality of first recess portions 1224 may be arranged parallel to each other in the second direction Z.

As a result, the substrate bar 1220 may have a shape extending in a zigzag manner as a whole.

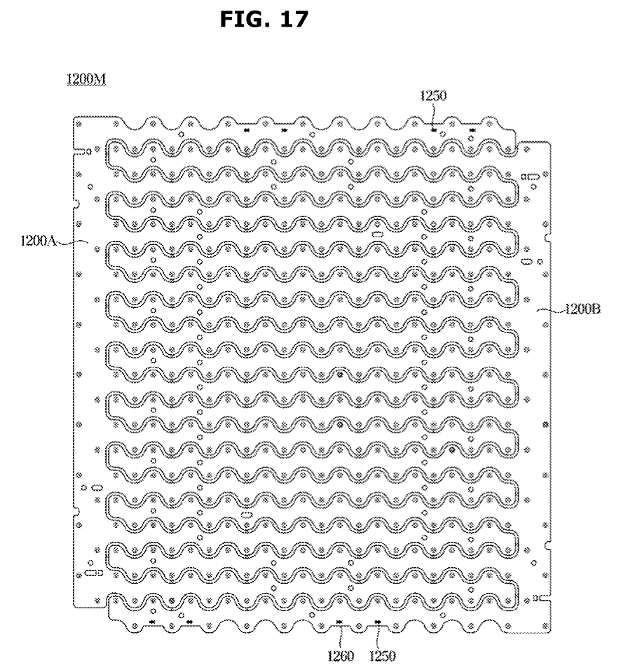

The shapes of protruding portions 1222a and 1222b and the shapes of recess portions 1223a and 1223b of the substrate bar 1220 may be different from each other. Therefore, the efficiency of the process of manufacturing the light source substrate 1200 may be improved. As an example, when performing a process of manufacturing a plurality of light source substrates 1200A and 1200B from a single substrate material 1200M, it may be easier to separate substrate bars 1220A and 1220B included in different light source substrates 1200A and 1200B when the shapes of each protruding portion 1222a, 1222b and each recess portion 1223a, 1223b arranged in parallel differ from each other, than in a case in which the shapes are the same. Through this, the manufacturing cost of the product may be reduced (refer to FIG. 17).

In some of the plurality of substrate bars 1220, shapes from the plurality of light sources 1100 to the plurality of first protruding portions 1222 and shapes from the plurality of light sources 1100 to the plurality of second protruding portions 1223 may be different from each other.

For example, in some of the plurality of substrate bars 1220, shapes of the edges of the plurality of first protruding portions 1222 and the shapes of the plurality of second protruding portions 1223 may be different from each other.

In some of the plurality of substrate bars 1220, distances d1 from the plurality of light sources 1100 to the edges (and/or borders, perimeters, outer surfaces) of the plurality of first protruding portions 1222 may be different from distances d2 from the plurality of light sources 1100 to the edges (and/or borders, perimeters, outer surfaces) of the plurality of second protruding portions 1223.

The “edge of the first protruding portion 1222” or “outer surface of the first protruding portion 1222” may refer to a part of the outer edge portion of the substrate bar 1220, specifically the outer edge portion of the part in which the first protruding portion 1222 is provided in the substrate bar 1220. The “edge of the first protruding portion 1222” may be used in a meaning corresponding to terms such as “outline of the first protruding portion 1222” or “profile of the first protruding portion 1222”.

Similarly, the “edge of the second protruding portion 1223” or “outer surface of the second protruding portion 1223” may refer to a part of the outer edge portion of the substrate bar 1220, specifically the outer edge portion of the part in which the second protruding portion 1223 is provided in the substrate bar 1220. The “edge of the second protruding portion 1223” may be used in a meaning corresponding to terms such as “outline of the second protruding portion 1223” or “profile of the second protruding portion 1223”.

The distance from each of the plurality of light sources 1100 to the edge of each of the plurality of first protruding portions 1222 and the distance from each of the plurality of light sources 1100 to the edge of each of the plurality of second protruding portions 1223 may be different from each other in the second direction Z.

The plurality of light sources 1100 may include a first light source 1110 disposed on the first protruding portion 1222 of the plurality of substrate bars 1220 and a second light source 1120 disposed on the second protruding portion 1223 of the plurality of substrate bars 1220. The shape from the first light source 1110 to the edge of the first protruding portion 1222 and the shape from the second light source 1120 to the edge of the second protruding portion 1223 may be different from each other.

For example, the distance in the second direction Z from the first light source 1110 to the edge of the first protruding portion 1222 and the distance in the second direction Z from the second light source 1120 to the edge of the second protruding portion 1223 may be different from each other. However, the preset disclosure is not limited thereto, and the shape and/or distance in the second direction Z from the first light source 1110 to the edge of the first protruding portion 1222 and the shape and/or distance in the second direction Z from the second light source 1120 to the edge of the second protruding portion 1223 may be the same.

The plurality of substrate bars 1220 may include a first substrate bar 1220a (refer to FIGS. 8 and 9), a second substrate bar 1220b (refer to FIGS. 11 and 12), and a third substrate bar 1220c. The first substrate bar 1220a may be disposed at a first end in the second direction. As an example, the first substrate bar 1220a may be provided at the upper end among the plurality of substrate bars 1220. The second substrate bar 1220b may be disposed at a first end in the third direction. As an example, the first substrate bar 1220 a may be provided at the lower end among the plurality of substrates 1220. The third substrate bar 1220c may be disposed between the first substrate bar 1220a and the second substrate bar 1220b in the vertical direction (or horizontal direction). As an example, the third substrate bar 1220c may include a plurality of third substrate bars 1220c. Therefore, in the plurality of substrate bars 1220c excluding the upper substrate bar 1220a and the lower substrate bar 1220b, the distance from the first light source 1110c to the first protruding portion 1222c and the distance from the second light source 1120c to the second protruding portion 1223c may be the same.

In the first substrate bar 1220a, a distance d1 from the first light source 1110a of the first substrate bar 1220a to the edge of the first protruding portion 1222a may be greater than the distance d2 from the second light source 1120a of the first substrate bar 1220a to the edge of the second protruding portion 1223a. In the second substrate bar 1220b, a distance d2’ from the second light source 1120b of the second substrate bar 1220b to the edge of the second protruding portion 1223b may be greater than the distance d1’ from the first light source 1110b of the second substrate bar 1220b to the edge of the first protruding portion 1222b.

In the third substrate bar 1220c, a distance d1’’ from the first light source 1110c of the third substrate bar 1220c to the edge of the first protruding portion 1222c and a distance d2’’ from the second light source 1120c of the third substrate bar 1220c to the edge of the second protruding portion 1223c may be the same.

For example, a distance d1 from the first light source 1110a of the first substrate bar 1220a to the edge of the first protruding portion 1222a may be greater than a distance d1’’ from the first light source 1110c of the third substrate bar 1220c to the edge of the first protruding portion 1222c. A distance d2’ from the second light source 1120b of the second substrate bar 1220b to the edge of the second protruding portion 1223b may be greater than a distance d2’’ from the second light source 1120c of the third substrate bar 1220c to the edge of the second protruding portion 1223c.

In addition, for example, a distance d2 from the second light source 1120a of the first substrate bar 1220a to the edge of the second protruding portion 1223a, a distance d1’ from the first light source 1110b of the second substrate bar 1220b to the edge of the first protruding portion 1222b, a distance d1’’ from the first light source 1110c of the third substrate bar 1220c to the edge of the first protruding portion 1222c, and/or a distance d2’’ from the second light source 1120c of the third substrate bar 1220c to the edge of the second protruding portion 1223c may be the same.

The distance d1 from the first light source 1110a of the first substrate bar 1220a to the edge of the first protruding portion 1222a may be a first distance d1. The distance d2’ from the second light source 1120b of the second substrate bar 1220b to the edge of the second protruding portion 1223b may be a second distance d2’.

The distance d2 from the second light source 1120a of the first substrate bar 1220a to the edge of the second protruding portion 1223a, the distance d1’ from the first light source 1110b of the second substrate bar 1220b to the edge of the first protruding portion 1222b, the distance d1’’ from the first light source 1110c of the third substrate bar 1220c to the edge of the first protruding portion 1222c, and/or the distance d2’’ from the second light source 1120c of the third substrate bar 1220c to the edge of the second protruding portion 1223c may be a third distance. However, the ordinal numbers and names of the first distance, second distance, and third distance are not limited to the above examples.

In other words, the first distance d1 may be greater than the third distances d2, d1’, d1’’, and d2’’, and the second distance d2’ may be greater than the third distances d2, d1’, d1’’, and d2’’. The first protruding portion 1222a of the first substrate bar 1220a on which the first light source 1110a is disposed may be disposed between the middle mold 14 and the bottom chassis 15 (refer to FIG. 13). In addition, the second protruding portion 1223b of the second substrate bar 1220b on which the second light source 1120b is disposed may be disposed between the middle mold 14 and the bottom chassis 15.

Since the first distance d1 and the second distance d2’ are greater than the third distances d2, d1’, d1’’, and d2’’, the light source substrate 1200 and the backlight unit 100 including the same may have strong resistance to external impact and be robust.

The distances and/or thicknesses in the second and third directions of each of the plurality of substrate bars 1220 may be the same. However, due to the length relationship of the first distance, second distance, and third distance, the length/distance L3 of the central extension portion 1221c of the third substrate bar 1220c may be greater than the length/distance L1 of the central extension portion 1221a of the first substrate bar 1220a and/or the length/distance L2 of the central extension portion 1221b of the second substrate bar 1220b. Through this, since the central extension portion 1221c of the third substrate bar 1220c has a longer length and a larger area than the central extension portion 1221a of the first substrate bar 1220a and/or the central extension portion 1221b of the second substrate bar 1220b, a supporter 150 for supporting the optical sheet 140 may be disposed on the central extension portion 1221c of the third substrate bar 1220c.

Therefore, according to the disclosure, the display apparatus 1 may not only stably fix the light source substrate 1200, but also dispose various components including the supporter 150 on the light source substrate 1200.

FIG. 13 is a cross-sectional view illustrating a display apparatus according to an embodiment of the present disclosure. FIG. 13 is a cross-sectional view taken along line E-E’ in the display apparatus shown in FIG. 7. In FIG. 13, a cross-section in which the first substrate bar is cut is illustrated.

Referring to FIGS. 8, 11, and 13, at least a part of the substrate bar 1220 may be disposed between the middle mold 14 and the bottom chassis 15 in the third direction X. As an example, the middle mold 14, the substrate bar 1220, and the bottom chassis 15 may be sequentially arranged along the front-rear direction.

The bottom chassis 15 and the middle mold 14 may be coupled. As an example, an insertion protrusion 15b protruding forward from the edge of the bottom chassis 15 may be inserted and/or accommodated in an accommodation groove 14b of the middle mold 14. In addition, a hook 14c of the middle mold 14 may be inserted into a hole of the bottom chassis 15.

At least a part of the substrate bar 1220 may be disposed between the middle mold 14 and the bottom chassis 15. As an example, the first protruding portion 1222a of the first substrate bar 1220a may be disposed between the middle mold 14 and the bottom chassis 15. Although FIG. 13 shows that the first protruding portion 1222a of the first substrate bar 1220a is disposed between the middle mold 14 and the bottom chassis 15, the second protruding portion 1223b of the second substrate bar 1220b may also be disposed between the middle mold 14 and the bottom chassis 15.

For example, first surfaces 1228 of the first substrate bar 1220a and the second substrate bar 1220b may face one surface (e.g., a rear surface 14a) of the middle mold 14, and second surfaces 1229 of the first substrate bar 1220a and the second substrate bar 1220b may face one surface (e.g., a front surface 15a) of the bottom chassis 15. For example, the first protruding portion 1222a of the first substrate bar 1220a and the second protruding portion 1223b of the second substrate bar 1220b may be in contact with one surface (e.g., a rear surface 14a) of the middle mold 14 and one surface (e.g., a front surface 15a) of the bottom chassis 15, respectively.

As described above, since the substrate body 1210 and the substrate bar 1220 are connected to form the light source substrate 1200, and the first distance d1 and/or the second distance d2’ are provided longer than the third distances d2, d1’, d1’’, and d2’’, the first protruding portion 1222a of the first substrate bar 1220a and the second protruding portion 1223b of the second substrate bar 1220b may be disposed between the middle mold 14 and the bottom chassis 15. In addition, a first end 1226 (e.g., a right end) and/or a second end (e.g., a left end) in the second direction of the substrate bar 12220 extending to the middle mold 14 may also be disposed between the middle mold 14 and the bottom chassis 15. Therefore, the light source substrate 1220 may be fixed by the middle mold 14 and the bottom chassis 15 at the edge.

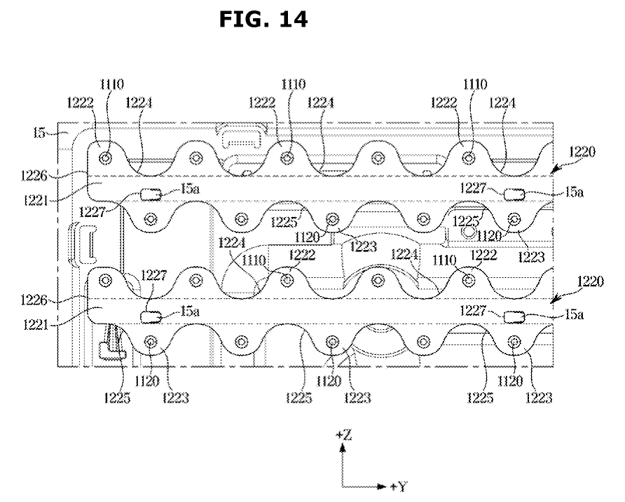

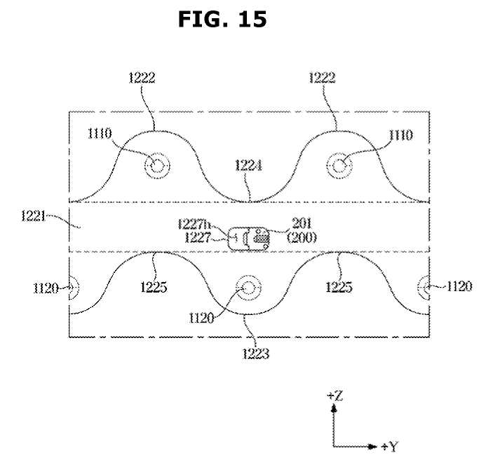

FIG. 14 is an enlarged view illustrating a portion of a substrate bar and a bottom chassis of a display apparatus according to an embodiment of the present disclosure. FIG. 15 is an enlarged view illustrating a substrate bar and a bar fixer coupled thereto in a display apparatus according to an embodiment of the present disclosure. In FIGS. 14 and 15, the middle mold is omitted.

Referring to FIGS. 14 and 15, in the display apparatus 1 according to an embodiment of the disclosure, the light source substrate 1200 may be mounted on the bottom chassis 15. As an example, the display apparatus 1 may include a board fixer 200, and the board fixer 200 may be provided to fix the light source substrate 1200 to the bottom chassis 15. As an example, the light source substrate 1200 may be mounted on the bottom chassis 15 through the board fixer 200.

The display apparatus 1 may include a bar fixer 201. The bar fixer 201 may be configured to fix the substrate bar 1220 to the bottom chassis 15. The bar fixer 201 may be provided as a plurality of bar fixers 201, and the plurality of bar fixers 201 may be provided to fix the plurality of substrate bars 1220 to the bottom chassis 15. The bar fixer 201 may be a type of the above-described board fixer 200. As an example, a plurality of board fixers 200 may include a bar fixer 201. At least some (for example, bar fixers 201) of the plurality of board fixers 200 may be provided to fix the substrate bar 1220 to the bottom chassis 15.

The bar fixer 201 may be mounted on the bottom chassis 15. The bottom chassis 15 may include a mounting portion 15a provided to mount the bar fixer 201 thereon. The bar fixer 201 may be fixed to the bottom chassis 15 by being mounted on the mounting portion 15a. As the bar fixer 201 is mounted on the bottom chassis 15, the substrate bar 1220 may be fixed to the bottom chassis 15. The bottom chassis 15 may include a plurality of mounting portions 15a corresponding in number to the plurality of bar fixers 201.

Each of the plurality of substrate bars 1220 may include a coupling portion 1227. Each of the plurality of substrate bars 1220 may be coupled to the bottom chassis 15 through the coupling portion 1227. The coupling portion 1227 may include a substrate hole 1225h. The bar fixer 201 may be disposed at the coupling portion 1227 of each of the plurality of substrate bars 1220. As an example, the bar fixer 201 may be coupled to the coupling portion 1227 of each of the plurality of substrate bars 1220. As an example, the number of the coupling portions 1227 may correspond to the number of the bar fixers 201. The coupling portion 1227 of the substrate bar 1220 may also be referred to as a bar coupling portion 1227.

The bar fixer 201 may be disposed at the coupling portion 1227 of the substrate bar 1220 to couple the coupling portion 1227 to the bottom chassis 15. As the bar fixer 201 is mounted on the mounting portion 15a of the bottom chassis 15, the substrate bar 1220 may be fixed to the bottom chassis 15.

As an example, each of the plurality of bar fixers 201 may be detachably mounted on the bottom chassis 15. As a result, each of the plurality of substrate bars 1220 may be detachably mounted on the bottom chassis 15.

Therefore, the light source substrate 1200 may be fixed between the middle mold 14 and the bottom chassis 15 at the edge by the first protruding portion 1222 of the first substrate bar 1220a and the second protruding portion 1223 of the second substrate bar 1220b, and by the end portion 1226 in the second direction of the substrate bar 12220, and may be fixed between the middle mold 14 and the bottom chassis 15 in regions excluding the edge of the light source substrate 1200 by the bar fixer 201.

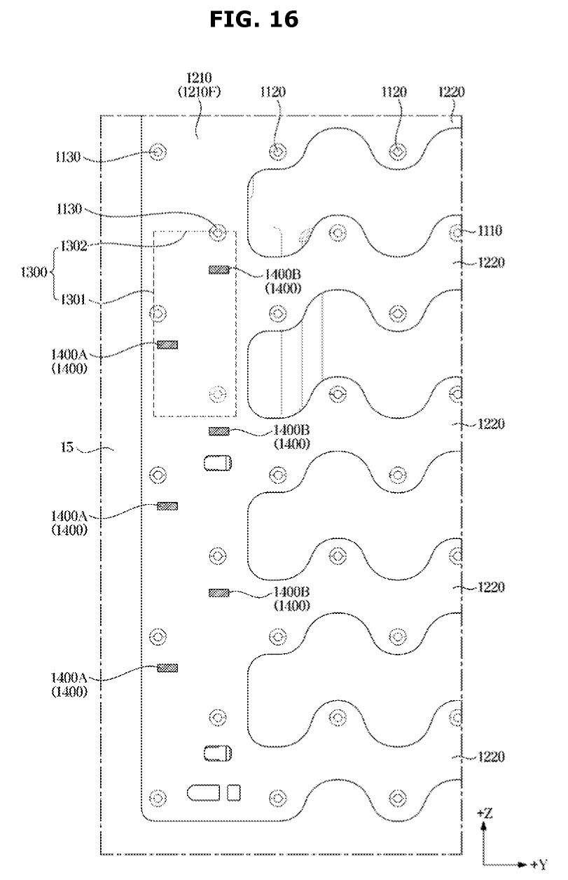

FIG. 16 is an enlarged view illustrating a portion of a light source module of a display apparatus according to an embodiment of the present disclosure.

Referring to FIG. 16, some light sources 1130 among the plurality of light sources 1100 may be mounted on the substrate body 1210. Hereinafter, for convenience of description, the light source 1130 mounted on the substrate body 1210 is referred to as a body light source 1130.

As an example, a plurality of body light sources 1130 may be mounted on the substrate body 1210. As an example, the plurality of body light sources 1130 may be arranged spaced apart at uniform intervals.

Some of the plurality of body light sources 1130 may be arranged along the second direction Z, in parallel with the plurality of light sources (i.e., first -side light sources 1110) mounted on the plurality of first protruding portions 1222 provided on one substrate bar 1220 among the plurality of substrate bars 1220. In this case, the body light sources 1130 and the first -side light sources 1110 may be arranged at uniform intervals along the second direction Z.

Other some of the plurality of body light sources 1130 may be arranged along the second direction Z, in parallel with to the plurality of light sources (i.e., second -side light sources 1120) mounted on the plurality of second protruding portions 1223 provided on one substrate bar 1220 among the plurality of substrate bars 1220. In this case, the body light sources 1130 and the second -side light sources 1120 may be arranged at uniform intervals along the second direction Z.

With such a structure, the uniformity of luminance may be improved not only in the area corresponding to the position of the plurality of substrate bars 1220 but also in the overall area of the screen including the area corresponding to the position of the substrate body 1210 in the screen provided by the display apparatus 1.

As described above, the connector 1300 may be mounted on the rear surface of the substrate body 1210. Here, the rear surface of the substrate body 1210 refers to one side of the substrate body 1210 facing the bottom chassis 15.

As an example, the connector 1300 may be formed to have a long side 1301 and a short side 1302. As an example, the long side 1301 and the short side 1302 of the connector 1300 may be provided to be perpendicular to each other, but the preset disclosure is not limited thereto.

In this case, the long side 1301 of the connector 1300 may be parallel to the second direction Z. That is, the connector 1300 may be arranged such that the long side 1301 thereof is parallel to the second direction Z. In other words, the connector 1300 may be arranged such that the length in the second direction Z is longer than the length in the first direction Y, and may extend long in the second direction Z.

Since the long side 1301 of the connector 1300 is parallel to the second direction Z, the amount of material used to manufacture the substrate body 1210 may be reduced, and the manufacturing cost of the product may be reduced.

As an example, a wire connected to the control assembly 50 or the power assembly 60 (or a separate printed circuit board assembly directly connected thereto) may be provided to be electrically connected to the connector 1300 through a terminal (not shown) provided on the long side 1301 side of the connector 1300. In addition, as an example, the power supply line 1230 of the light source substrate 1200 may be provided to be electrically connected to the connector 1300 through a terminal (not shown) provided on the long side 1301 side of the connector 1300.

The display apparatus 1 may include a plurality of driving elements 1400 mounted on the light source substrate 1200. The plurality of driving elements 1400 may be provided to control at least some of the light sources 1100 among the plurality of light sources 1100 mounted on the same light source substrate 1200.

The plurality of driving elements 1400 may be mounted on the light source substrate 1200 and electrically connected to the power supply line 1230. The plurality of driving elements 1400 may be electrically connected to the control assembly 50 and/or the power assembly 60 through components such as the power supply line 1230 and the connector 1300.

As an example, the plurality of light sources 1100 may be divided into a plurality of dimming blocks including at least one light source 1100, and the plurality of driving elements 1400 may be provided to control the plurality of dimming blocks by outputting dimming signals.

As an example, the plurality of driving elements 1400 may be implemented as pixel integrated circuits (ICs) or active matrix integrated circuits (AM ICs).

The plurality of driving elements 1400 may be mounted on a front surface 1210F of the substrate body 1210. Here, the front surface 1210F of the substrate body 1210 may refer to one side of the substrate body 1210 facing the display panel 20.

In this case, the reflective sheet 120 may be attached to the front surface of the substrate body 1210. As a result, driving element through-portions may be formed in the reflective sheet 120 at regions corresponding to the positions of the plurality of driving elements 1400, and each of the plurality of driving elements 1400 may penetrate the corresponding driving element through-portion and protrude toward the front side of the reflective sheet 120.

The plurality of driving elements 1400 may be arranged on the front surface 1210F of the substrate body 1210 such that the positions thereof in the second direction Z are different from each other, and some of the driving elements 1400 among the plurality of driving elements 1400 may be arranged such that the positions thereof in the first direction Y are different from those of other driving elements 1400.

The plurality of driving elements 1400 may include driving elements 1400A in a first column and driving elements 1400B in a second column.

The driving elements 1400A in the first column may be arranged along the second direction Z. Specifically, the driving elements 1400A included in the driving elements 1400A in the first column may be arranged to be spaced apart from each other along the second direction Z.

In addition, the driving elements 1400B in the second column may be arranged along the second direction Z. Specifically, the driving elements 1400B included in the driving elements 1400B in the second column may be arranged to be spaced apart from each other along the second direction Z.

Here, the driving elements 1400A in the first column and the driving elements 1400B in the second column may be arranged to be spaced apart from each other. As an example, each driving element 1400A included in the driving elements 1400A in the first column and each driving element 1400B included in the driving elements 1400B in the second column may be arranged such that the positions thereof in the first direction Y are spaced apart from each other. As an example, the plurality of driving elements 1400A may be arranged in a zigzag manner on the front surface 1210F of the substrate body 1210.

With such a structure, it is possible to prevent a reduction in reflectance and luminance of the reflective sheet 120 from being concentrated in specific regions due to the through-holes for the driving elements, thereby improving luminance uniformity of the display apparatus 1.

FIG. 17 is a schematic view illustrating a light source substrate of a display apparatus according to an embodiment of the present disclosure.

Referring to FIG. 17, the light source substrate 1200 used in the display apparatus 1 according to an embodiment of the disclosure may be manufactured by a method of manufacturing a plurality of light source substrates 1200A and 1200B from a single substrate material 1200M.

A single substrate material 1200M in which a plurality of light source substrates 1200A and 1200B are designed may be prepared. The single substrate material 1200M may be provided in the form of an integral plate.

On the single substrate material 1200M, components of the display apparatus such as the plurality of light sources 1100, the connector 1300, and/or the driving element 1400 may be mounted. A mounting device for mounting the components may have coordinates regarding information on desirable mounting positions of each of the components such as the plurality of light sources 1100, the connector 1300, and/or the driving element 1400 mounted on the substrate material 1200M.

While the components of the display apparatus are being mounted on the substrate material 1200M, the substrate material 1200M may thermally expand or contract. Accordingly, the components such as the plurality of light sources 1100, the connector 1300, and/or the driving element 1400 may be mounted at positions different from the desirable mounting positions.

The substrate material 1200M used in the display apparatus according to an embodiment of the disclosure may be provided with a reference mark 1250. The reference mark 1250 may be provided on a flat portion 1260. The flat portion 1260 may be provided between the plurality of protruding portions 1222.

The reference mark 1250 may prevent the components from being mounted at positions different from the desirable mounting positions due to thermal expansion or contraction as described above. As an example, the mounting device may use the reference mark 1250 as a reference point. Even when the substrate material 1200M thermally expands or contracts, the mounting device may reset the zero point based on the reference mark 1250 to arrange the components such as the plurality of light sources 1100, the connector 1300, and/or the driving element 1400 at the desirable mounting positions. Therefore, the components may not be mounted at incorrect positions.

The single substrate material 1200M may illustrate a pair of light source substrates 1200A and 1200B arranged to be inverted by 180 degrees relative to each other. The substrate bar 1220 provided on one of the pair of light source substrates 1200A and 1200B and the substrate bar 1220 provided on the other may be arranged to intersect each other. As an example, between a pair of adjacent substrate bars 1220 provided on one of the pair of light source substrates 1200A and 1200B (for example, 1200A), one substrate bar 1220 provided on the other light source substrate (for example, 1200B) may be positioned. In addition, the pair of light source substrates 1200A and 1200B may be arranged such that respective substrate bodies 1210 are positioned on the opposite sides.

Thereafter, an operation of separating each of the pair of light source substrates 1200A and 1200B by cutting along edges of the pair of light source substrates 1200A and 1200B shown on the single substrate material 1200M using a tool may be performed. As an example, the tool T may include various processing devices such as a router.

By the above-described method, substrate bars included in the pair of light source substrates 1200A and 1200B may be formed from the single substrate material 1200M and then separated through the tool. In addition, by cutting along the edges of the pair of light source substrates 1200A and 1200B, unnecessary removal of portions during the process of manufacturing the plurality of light source substrates 1200A and 1200B from the single substrate material 1200M may be reduced, thereby preventing material waste and reducing costs. n. In other words, since a plurality of light source substrates 1200A and 1200B may be manufactured from a single substrate material 1200M, waste of materials may be prevented and manufacturing procedures may be reduced, thereby reducing manufacturing costs.

According to one aspect of the disclosure, it is possible to provide a display apparatus in which a light source substrate may be stably fixed within a main body, by increasing a length of a protruding portion of a substrate bar disposed at an outermost side among a plurality of substrate bars.

The effects of the disclosure are not limited to those described above, and other effects that are not described above will be clearly understood by those skilled in the art from the above detailed description.

A display apparatus according to an embodiment includes a display panel 20, a plurality of light sources 1100 configured to emit light toward the display panel and including first light sources 1110 and second light sources 1120, and a plurality of substrate bars 1220 on which the plurality of light sources are mounted, wherein each of the plurality of substrate bars includes a central extension portion 1221 extending in a first direction Y, a first protruding portion 1222 protruding from the central extension portion in a second direction Z different from the first direction such that the first light source 1110 is mounted thereon, and a second protruding portion 1223 protruding from the central extension portion in a third direction -Z opposite to the second direction such that the second light source 1120 is mounted thereon.

In some of the plurality of substrate bars, a distance d1 from the first light source to an edge of the first protruding portion 1222 and a distance d2 from the second light source to an edge of the second protruding portion 1223 may be different.

The plurality of substrate bars 1220 include a first substrate bar 1220a provided at a first end along the second direction among the plurality of substrate bars, and a second substrate bar 1220b provided at a first end along the third direction among the plurality of substrate bars, wherein a distance d1 from a first light source 1110a mounted on the first substrate bar to an edge of the first protruding portion 1222a of the first substrate bar is greater than a distance d2 from a second light source 1120a mounted on the first substrate bar to an edge of the second protruding portion 1223a of the first substrate bar, and a distance d2’ from a second light source 1120b mounted on the second substrate bar to an edge of the second protruding portion 1223b of the second substrate bar is greater than a distance d1’ from a first light source 1110b mounted on the second substrate bar to an edge of the first protruding portion 1222b of the second substrate bar.

The plurality of substrate bars 1220 further include a third substrate bar 1220c provided between the first substrate bar and the second substrate bar, wherein the distance d1 from the first light source mounted on the first substrate bar to the edge of the first protruding portion 1222 of the first substrate bar is greater than a distance d1’’ from a first light source mounted on the third substrate bar to an edge of the first protruding portion 1222c of the third substrate bar, and the distance d2’ from the second light source mounted on the second substrate bar to the edge of the second protruding portion 1223b of the second substrate bar is greater than a distance d2’’ from a second light source mounted on the third substrate bar to an edge of the second protruding portion 1223c of the third substrate bar.

The display apparatus may further include a bottom chassis 15 on which the plurality of substrate bars are disposed, and a middle mold 14 coupled to the bottom chassis and configured to fix the first protruding portion of the first substrate bar and the second protruding portion of the second substrate bar.

The first protruding portion of the first substrate bar and the second protruding portion of the second substrate bar may be disposed between the middle mold and the bottom chassis.

The second direction and the third direction may each be perpendicular to the first direction.

The display apparatus may further include a plurality of bar fixers 201 disposed on the central extension portion to fix the plurality of substrate bars to the bottom chassis.

The display apparatus may further include a diffuser plate 130 and an optical sheet 140 disposed between the display panel and the plurality of light sources, and a supporter 150 disposed on the central extension portion of the third substrate bar to support the optical member.

The first protruding portion includes a plurality of first protruding portions, and the second protruding portion includes a plurality of second protruding portions, and each of the plurality of substrate bars may further include a plurality of first recess portions 1224 each formed between a pair of first protruding portions adjacent to each other among the plurality of first protruding portions and a plurality of second recess portions 1225 each formed between a pair of second protruding portions adjacent to each other among the plurality of second protruding portions.

The display apparatus may further include a reference mark 1250 having a step difference along the first direction with respect to the plurality of first recess portions, wherein a distance between the plurality of first protruding portions and the reference mark may be smaller than a distance between the plurality of first protruding portions and the plurality of first recess portions.

The display apparatus may further include a substrate body 1210 on which some light sources 1130 among the plurality of light sources are mounted and extending in the first direction such that the plurality of substrate bars are connected, wherein each of the plurality of substrate bars may extend from the substrate body.

Some of the light sources mounted on the substrate body are arranged parallel to a plurality of light sources mounted on the first protruding portion along the first direction Y, and other light sources mounted on the substrate body are arranged parallel to a plurality of light sources mounted on the second protruding portion along the first direction Y.

The display apparatus may further include a plurality of driving elements 1400 mounted on one surface 1210F of the substrate body facing the display panel and configured to control at least some of the light sources among the plurality of light sources, wherein the plurality of driving elements are arranged at different positions in the second direction, and some of the plurality of driving elements may be arranged at positions different from positions of other driving elements among the plurality of driving elements in the first direction.

The plurality of driving elements include a first column of driving elements arranged along the second direction and a second column of driving elements spaced apart from the first column of driving elements and arranged along the second direction, wherein each driving element included in the first column and each driving element included in the second column may be arranged to be spaced apart from each other in the second direction.

A display apparatus according to an embodiment includes a display panel 20 and a plurality of light sources 1100 including a first light source 1110 and a second light source 1120 configured to emit light toward the display panel, and a substrate bar 1220 on which the plurality of light sources are mounted, wherein the substrate bar includes a central extension portion 1221 extending in a first direction Y, a first protruding portion 1222 protruding from the central extension portion in a second direction Z and on which the first light source is mounted, and a second protruding portion 1223 protruding from the central extension portion in a third direction -Z different from the second direction and on which the second light source is mounted.

A distance from the first light source 1110 to an edge of the first protruding portion 1222 and a distance from the second light source 1120 to an edge of the second protruding portion 1223 may be different.

The plurality of substrate bars include a first substrate bar 1220a provided at a first end along the second direction among the plurality of substrate bars and a second substrate bar 1220b provided at a first end along the third direction among the plurality of substrate bars, wherein a distance from a first light source of the first substrate bar to the plurality of first protruding portions of the first substrate bar is greater than a distance from a second light source of the first substrate bar to the plurality of second protruding portions of the first substrate bar, and a distance from a second light source of the second substrate bar to the plurality of second protruding portions of the second substrate bar is greater than a distance from a first light source of the second substrate bar to the plurality of first protruding portions of the second substrate bar.

The plurality of substrate bars further include a third substrate bar 1220c provided between the first substrate bar and the second substrate bar, wherein a distance from a first light source of the first substrate bar to the plurality of first protruding portions of the first substrate bar is greater than a distance from a first light source of the third substrate bar to the plurality of first protruding portions of the third substrate bar, and a distance from a second light source of the second substrate bar to the plurality of second protruding portions of the second substrate bar is greater than a distance from a second light source of the third substrate bar to the plurality of second protruding portions of the third substrate bar.

The display apparatus may further include a diffuser plater 130 and an optical sheet 140 disposed between the display panel and the first and second light sources, and a supporter 150 disposed on the central extension portion of the third substrate bar to support the optical members.

A display apparatus according to an embodiment includes a display panel 20, a bottom chassis 15 configured to support the display panel, a middle mold 14 coupled to the bottom chassis at an edge of the bottom chassis, a light source substrate 1200 disposed on the bottom chassis and on which a light source is mounted, and a plurality of bar fixers 201 configured to fix the light source substrate to the bottom chassis, wherein the light source substrate 1200 includes a substrate body 1210 extending along a first direction Z, a plurality of central extension portions 1221 spaced apart from each other in the first direction Z and extending from the substrate body in a second direction Y such that the plurality of bar fixers 201 are disposed thereon, a first protruding portion 1222 protruding from a first side of each of the plurality of central extension portions, and a plurality of second protruding portions 1223 protruding from a second side of each of the plurality of central extension portions, wherein the plurality of first protruding portions and the plurality of second protruding portions are disposed between the middle mold and the bottom chassis to fix the light source substrate.

Although example embodiments of the disclosure have been described in detail, those of ordinary skill in the technical field to which the disclosure pertains should be able to understand that various modifications and alterations may be made without departing from the technical spirit and scope of the present disclosure.

What is claimed is:

1. A display apparatus comprising:
a display panel;
a plurality of light sources configured to emit light toward the display panel and comprising first light sources and second light sources; and
a plurality of substrate bars on which the plurality of light sources are mounted, wherein each of the plurality of substrate bars comprises:
a central extension portion extending in a first direction;
a first protruding portion protruding from the central extension portion in a second direction different from the first direction, a first light source among the first light sources being mounted on the first protruding portion; and
a second protruding portion protruding from the central extension portion in a third direction opposite to the second direction, a second light source among the second light sources being mounted on the second protruding portion,
wherein in at least one of the plurality of substrate bars, a shape from the first light source to the first protruding portion is different from a shape from the second light source to the second protruding portion.

2. The display apparatus of claim 1, wherein in at least one of the plurality of substrate bars, a distance from the first light source to an edge of the first protruding portion is different from a distance from the second light source to an edge of the second protruding portion.

3. The display apparatus of claim 2, wherein the plurality of substrate bars comprises:
a first substrate bar at an end in the second direction among the plurality of substrate bars; and
a second substrate bar at an end in the third direction among the plurality of substrate bars,
wherein a distance from the first light source mounted on the first substrate bar to the edge of the first protruding portion of the first substrate bar is greater than a distance from the second light source mounted on the first substrate bar to the edge of the second protruding portion of the first substrate bar, and
wherein a distance from the second light source mounted on the second substrate bar to the edge of the second protruding portion of the second substrate bar is greater than a distance from the first light source mounted on the second substrate bar to the edge of the first protruding portion of the second substrate bar.

4. The display apparatus of claim 3, wherein the plurality of substrate bars further comprises a third substrate bar between the first substrate bar and the second substrate bar,
wherein the distance from the first light source mounted on the first substrate bar to the edge of the first protruding portion of the first substrate bar is greater than a distance from the first light source mounted on the third substrate bar to the edge of the first protruding portion of the third substrate bar, and
wherein the distance from the second light source mounted on the second substrate bar to the edge of the second protruding portion of the second substrate bar is greater than a distance from the second light source mounted on the third substrate bar to the edge of the second protruding portion of the third substrate bar.

5. The display apparatus of claim 4, further comprising:
a bottom chassis on which the plurality of substrate bars are disposed; and
a middle mold coupled to the bottom chassis and configured to fix the first protruding portion of the first substrate bar and the second protruding portion of the second substrate bar.

6. The display apparatus of claim 5, wherein the first protruding portion of the first substrate bar and the second protruding portion of the second substrate bar are between the middle mold and the bottom chassis.

7. The display apparatus of claim 6, wherein each of the second direction and the third direction is perpendicular to the first direction.

8. The display apparatus of claim 7, further comprising a plurality of bar fixers on the central extension portion and configured to fix the plurality of substrate bars to the bottom chassis.

9. The display apparatus of claim 4, further comprising:
an optical member disposed between the display panel and the plurality of light sources; and
a supporter on the central extension portion of the third substrate bar and supporting the optical member.

10. The display apparatus of claim 4, wherein the first protruding portion comprises a plurality of first protruding portions,
wherein the second protruding portion includes a plurality of second protruding portions, and
wherein each of the plurality of substrate bars further comprises:
a plurality of first recess portions, each first recess portion being between a pair of adjacent first protruding portions among the plurality of first protruding portions; and
a plurality of second recess portions, each second recess portions being between a pair of adjacent second protruding portions among the plurality of second protruding portions.

11. The display apparatus of claim 10, further comprising a reference mark having a step difference along the second direction with respect to the plurality of first recess portions,
wherein a distance between the plurality of first protruding portions and the reference mark is smaller than a distance between the plurality of first protruding portions and the plurality of first recess portions.

12. The display apparatus of claim 1, further comprising a substrate body on which light sources of the plurality of light sources are mounted and extending in the second direction, the substrate body being connected to the plurality of substrate bars,
wherein each of the plurality of substrate bars extends from the substrate body.

13. The display apparatus of claim 12, wherein the first protruding portion comprises a plurality of first protruding portions,
wherein the second protruding portion comprises a plurality of second protruding portions,
wherein some of the light sources mounted on the substrate body are arranged parallel to the first light sources mounted on the plurality of first protruding portions along the first direction, and
wherein other light sources of the light sources mounted on the substrate body are arranged parallel to the second light sources mounted on the plurality of second protruding portions along the first direction.

14. The display apparatus of claim 12, further comprising a plurality of driving elements mounted on a surface of the substrate body facing the display panel and configured to control at least some of the light sources among the plurality of light sources,
wherein the plurality of driving elements are arranged at different positions in the second direction, and
wherein at least one driving element of the plurality of driving elements is arranged at a position in the first direction different from a position of at least one other driving element among the plurality of driving elements.

15. The display apparatus of claim 14, wherein the plurality of driving elements comprises:
a first column of driving elements arranged along the second direction; and
a second column of driving elements spaced apart from the first column of driving elements and arranged along the second direction, and
wherein each of the driving elements in the first column and each of the driving elements in the second column are arranged to be spaced apart from each other in the second direction.
